(19) United States
(12) Patent Application Publication
(10) Pub. No.: US 2024/0053411 A1
(43) Pub. Date: Feb. 15, 2024

(54) STORAGE BATTERY MANAGEMENT DEVICE AND METHOD FOR MANAGING BATTERY DEVICE

(71) Applicant: MUSASHI SEIMITSU INDUSTRY CO., LTD., TOYOHASHI-SHl, AICHI (JP)

(72) Inventor: Kenji HAMADA, TOYOHASHI-SHI, AICHI (JP)

(21) Appl. No.: 18/270,807

(22) PCT Filed: Jan. 27, 2021
(86) PCT No.: PCT/JP2021/002790

§ 371 Date: Jul. 3, 2023

(51) Int. Cl. G01R 31/396; G01R 31/392; H02J 7/00; H01M 10/42; H01M 10/48

(52) U.S. Cl. CPC G01R 31/396; G01R 31/392; H02J 7/0014; H01M 10/425; H01M 10/482; H01M 2010/4271

(57) ABSTRACT

A storage battery management device for managing an assembly of series connected storage batteries having SOC-OCV characteristics including a plateau region includes: a voltage equalization circuit that performs constant current control to reduce the voltage difference of each storage battery by transferring electric charge among the storage batteries; a coulomb counting processing unit that calculates the capacity of each storage battery; a target voltage calculation unit that sets a target voltage for each storage battery based on the average voltage and the internal resistance; and a voltage equalization control unit that controls the voltage equalization circuit to cause the voltage equalization circuit to perform the constant current control. If the average voltage is within the plateau region, the voltage equalization control unit continues constant current control when the capacity difference is ≥ a first capacity difference, and stops constant current control when the capacity difference reaches a second capacity difference.

### TECHNICAL FIELD

The technology disclosed herein relates to a storage battery management device and a method for managing a battery device.

### BACKGROUND ART

In a battery assembly in which a plurality of storage batteries are connected in series, when the voltage of each storage battery varies, for example, due to variations in the amount of self-discharge or the degree of deterioration of each storage battery, the discharge of the battery assembly is stopped when the storage battery with the lowest voltage reaches the lower voltage limit during the discharge of the battery assembly, so that it becomes impossible to use the electrical energy of the storage batteries that have not yet reached the lower voltage limit, thereby reducing the continuous operating time of the battery assembly. To avoid this situation, when the voltage of each storage battery varies, a voltage equalization process (cell balancing process) is performed to reduce the voltage variation of each storage battery. In the active voltage equalization process, which is one of the voltage equalization processes, constant current control is performed to bring the voltage of each storage battery closer to the target voltage by transferring electric charge (electrical energy) from the storage battery with the higher voltage to the storage battery with the lower voltage.

If the voltage equalization process uses the average of the voltages of multiple target storage batteries as the target voltage, the actual voltage attained by each storage battery through the voltage equalization process may deviate from the target voltage due to the effect of the internal resistance of each storage battery. The known technology to prevent this is to set the target voltage for each storage battery based on the average voltage of multiple storage batteries and the internal resistance of each storage battery (see, e.g., Patent Document 1).

### CITATION LIST

### Patent Literature

Patent Document 1: JP 2014-75953 A

### SUMMARY OF INVENTION

### Technical Problem

Some storage batteries, such as iron phosphate lithium-ion batteries, have SOC (State of Charge)—OCV (Open Circuit Voltage) characteristics that include a plateau region. The plateau region is a region where the curve representing the SOC-OCV characteristics is almost flat. When the conventional voltage equalization process described above is performed on a battery assembly with multiple storage batteries having SOC-OCV characteristics that include a plateau region, if the average voltage of the multiple storage batteries is in the plateau region, the change in voltage becomes small relative to the change in capacity of the storage batteries near the average voltage; therefore, there is a problem that even if the voltage of each storage battery reaches the target voltage, a relatively large difference in the capacity of each storage battery may remain at that time point, and the continuous operating time of the battery assembly cannot be effectively extended.

This document discloses a technology that can solve the above-mentioned problem.

### Solution to Problem

The technology disclosed herein may have the following aspects, for example.
(1) A first storage battery management device disclosed herein is a device for managing a battery assembly in which a first storage battery and a second storage battery having SOC-OCV characteristics including a plateau region are connected in series. The storage battery management device includes a voltage measuring unit, a current measuring unit, a voltage equalization circuit, a coulomb counting processing unit, an internal resistance estimation unit, a target voltage calculation unit, and a voltage equalization control unit. The voltage measuring unit measures the voltage of each of the first storage battery and the second storage battery. The current measuring unit measures the current flowing through the battery assembly. The voltage equalization circuit performs constant current control to reduce the difference between the voltage of the first storage battery and the voltage of the second storage battery by transferring electric charge between the first storage battery and the second storage battery. The coulomb counting processing unit integrates the current measured by the current measuring unit with the current during the constant current control to calculate the respective capacities of the first storage battery and the second storage battery. The internal resistance estimation unit estimates the internal resistance of each of the first storage battery and the second storage battery. The target voltage calculation unit sets a first target voltage of the first storage battery and a second target voltage of the second storage battery based on the average voltage of the first storage battery and the voltage of the second storage battery measured by the voltage measuring unit and the internal resistance estimated by the internal resistance estimation unit. The voltage equalization control unit controls the voltage equalization circuit to cause the voltage equalization circuit to perform the constant current control. If the average voltage is within the plateau region for at least one of the first storage battery and the second storage battery, when the voltage of the first storage battery reaches the first target voltage or the voltage of the second storage battery reaches the second target voltage during the constant current control, the voltage equalization control unit identifies the capacity difference between the capacity of the first storage battery and the capacity of the second storage battery calculated by the coulomb counting processing unit, and continues the constant current control when the capacity difference is greater than or equal to a predetermined first capacity difference, and stops the constant current control when the capacity difference reaches a predetermined second capacity difference, the absolute value of the second capacity difference being smaller than the absolute value of the first capacity difference.

According to this storage battery management device, in a battery assembly in which two storage batteries (the first storage battery and the second storage battery) having SOC-OCV characteristics including a plateau region are connected in series, even when the average voltage of the two storage batteries is within the plateau region and the constant current control referring to the target voltage may not be sufficient to accurately equalize the remaining capacity of each of the storage batteries, by performing constant current control referring to the capacity difference of the two storage batteries, it is possible to accurately equalize the remaining capacity of each storage battery, thereby effectively extending the continuous operating time of the battery assembly.
(2) In the above storage battery management device, when the average voltage changes during the constant current control, the target voltage calculation unit may update the first target voltage and the second target voltage based on the average voltage after the change. According to this storage battery management device, even if the average voltage of two storage batteries changes during constant current control for voltage equalization, the target voltage can be updated according to the change, and as a result, it is possible to accurately equalize remaining capacity of each of the storage batteries in the voltage equalization process, thereby effectively extending the continuous operating time of the battery assembly.
(3) In the above storage battery management device, the voltage equalization control unit may set the second capacity difference based on the difference between the FCC of the first storage battery and the FCC of the second storage battery. According to this storage battery management device, even if the FCC of each storage battery varies, it is possible to equalize the capacity of each storage battery so that the times when the remaining capacity of each storage battery becomes zero at the time of discharging the battery assembly are close to each other, thereby effectively extending the continuous operating time of the battery assembly.
(4) In the above storage battery management device, the voltage equalization control unit may set a sign inversed value of the difference between the FCC of the first storage battery and the FCC of the second storage battery as the second capacity difference. According to this storage battery management device, even if the FCC of each storage battery varies, it is possible to equalize the capacity of each storage battery so that the remaining capacity of each storage battery becomes zero almost simultaneously at the time of discharge of the battery assembly, thereby extremely effectively extending the continuous operating time of the battery assembly.
(5) The above storage battery management device may further include an SOH estimation unit that estimates the SOH of each of the first storage battery and the second storage battery, and the target voltage calculation unit may correct the internal resistance of each of the first storage battery and the second storage battery based on the SOH of each of the first storage battery and the second storage battery estimated by the SOH estimation unit, and set the first target voltage and the second target voltage based on the corrected internal resistance. According to this storage battery management device, it is possible to accurately set the target voltages based on the internal resistance corrected according to the SOH of each storage battery, and more accurately equalize the capacity of each storage battery in the voltage equalization process, thereby effectively extending the continuous operating time of the battery assembly.
(6) The above storage battery management device may further include a history unit that records the history of the current integrated amount of charge or discharge obtained by the coulomb counting processing unit and the integrated time of the charge or discharge, and the target voltage calculation unit may calculate the number of charge/discharge cycles based on the history recorded in the history unit, correct the internal resistance of the first storage battery and the second storage battery based on the number of charge/discharge cycles, and set the first target voltage and the second target voltage based on the corrected internal resistance. According to this storage battery management device, it is possible to accurately set the target voltages based on the internal resistance corrected according to the number of charge-discharge cycles of each storage battery, and more accurately equalize the capacity of each storage battery in the voltage equalization process, thereby effectively extending the continuous operating time of the battery assembly.
(7) The above storage battery management device may further include a communication unit for communicating with the outward, and the history recorded in the history unit may be updatable via the communication unit. According to this storage battery management device, even if, e.g., the storage battery is replaced, it is possible to correct the internal resistance based on the number of charge/discharge cycles calculated based on the externally updated history of the storage battery to accurately set the target voltage based on the corrected internal resistance, and more accurately equalize the capacity of each storage battery in the voltage equalization process, thereby effectively extending the continuous operating time of the battery assembly.
(8) The above storage battery management device may further include a battery temperature measuring unit that measures the temperature of at least one of the first storage battery and the second storage battery, and a recording unit having previously recorded table data in which battery voltage, battery temperature, and battery internal resistance are associated with each other, and the internal resistance estimation unit may refer to the table data to estimate the internal resistance based on the average voltage and the battery temperature. According to this storage battery management device, it is possible to accurately estimate the internal resistance of the storage batteries, and as a result, accurately set the target voltages of each storage battery, and accurately equalize the capacity of each storage battery in the voltage equalization process, thereby effectively extending the continuous operating time of the battery assembly.
(9) In the above storage battery management device, if the average voltage is within the plateau region for at least one of the first storage battery and the second storage battery, when the voltage of the first storage battery reaches the first target voltage or the voltage of the second storage battery reaches the second target voltage during the constant current control, the voltage equalization control unit may identify the capacity difference between the capacity of the first storage battery and the capacity of the second storage battery calculated by the coulomb counting processing unit, and stops the constant current control when the capacity difference is smaller than the first capacity difference. According to this storage battery management device, it is possible to promptly stop the constant current control when the capacity of each storage battery is sufficiently equalized by the constant current control referring to the target voltage, thereby reducing the processing time.
(10) In the above storage battery management device, if the average voltage is not within the plateau region of either the first storage battery and the second storage battery, when the voltage of the first storage battery reaches the first target voltage or the voltage of the second storage battery reaches the second target voltage during the constant current control, the voltage equalization control unit may stop the constant current control. According to this storage battery management device, in a case where the capacity of each storage battery can be sufficiently equalized by the constant current control referring to the target voltage since the average voltage of the two storage batteries is outside the plateau region, it is possible to promptly stop the constant current control without calculating the capacity difference between the storage batteries when one of the storage batteries reaches the target voltage during the voltage-referenced constant current control, thereby effectively reducing the processing time.
(11) In the above storage battery management device, the first storage battery may be a first battery module including a plurality of cells, and the second storage battery may be a second battery module including a plurality of cells. According to this storage battery management device, it is possible to accurately equalize the remaining capacity of each battery module, thereby effectively extending the continuous operating time of the battery assembly.
(12) The second storage battery management device disclosed herein is a device for managing a battery assembly in which a plurality of storage batteries having SOC-OCV characteristics including a plateau region are connected in series. The storage battery management device includes a voltage measuring unit, a current measuring unit, a voltage equalization circuit, a coulomb counting processing unit, an internal resistance estimation unit, a target voltage calculation unit, and a voltage equalization control unit. The voltage measuring unit measures the voltage of each of the plurality of storage batteries. The current measuring unit measures the current flowing through the battery assembly. The voltage equalization circuit performs constant current control for each of the plurality of storage batteries individually to reduce the voltage difference of each of the plurality of storage batteries by transferring electric charge among the plurality of storage batteries. The coulomb counting processing unit integrates the current measured by the current measuring unit with the current during the constant current control to calculate the capacity of each of the plurality of storage batteries. The internal resistance estimation unit estimates the internal resistance of each of the plurality of storage batteries. The target voltage calculation unit identifies at least one storage battery of the plurality of storage batteries in which the difference between the voltage of each of the plurality of storage batteries measured by the voltage measuring unit and the average voltage of the plurality of storage batteries is more than a predetermined value as a target storage battery, and sets a target voltage for each of the target storage batteries based on the average voltage and the internal resistance estimated by the internal resistance estimation unit. The voltage equalization control unit controls the voltage equalization circuit to cause the voltage equalization circuit to perform the constant current control for each of the target storage batteries individually. If the average voltage is within the plateau region, the voltage equalization control unit identifies, for the target storage battery that has reached the target voltage during the constant current control, a capacity difference from the average capacity of each of the plurality of storage batteries calculated by the coulomb counting processing unit, and continues the constant current control for the target storage battery for which the capacity difference is equal to or greater than a predetermined first capacity difference, and stops the constant current control for the target storage battery for which the capacity difference has reached a predetermined second capacity difference, the absolute value of the second capacity difference being smaller than the absolute value of the first capacity difference.

According to this storage battery management device, in a battery assembly in which a plurality of storage batteries having SOC-OCV characteristics including a plateau region are connected in series, even when the average voltage of each storage battery is within the plateau region and the constant current control referring to the target voltage may not be sufficient to accurately equalize the remaining capacity of each storage battery, by performing constant current control referring to the capacity difference of each storage battery, it is possible to accurately equalize the remaining capacity of each storage battery, thereby effectively extending the continuous operating time of the battery assembly.
(13) In the above storage battery management device, when the average voltage changes during the constant current control, the target voltage calculation unit may update the target voltage of each target storage battery based on the average voltage after the change. According to this storage battery management device, even if the average voltage of the storage batteries changes during constant current control for voltage equalization, the target voltage can be updated according to the change, and as a result, it is possible to accurately equalize remaining capacity of each of the storage batteries in the voltage equalization process, thereby effectively extending the continuous operating time of the battery assembly.
(14) In the above storage battery management device, the voltage equalization control unit may set the second capacity difference based on the difference between the FCC of the target storage battery and an average FCC of the plurality of storage batteries. According to this storage battery management device, even if the FCC of each storage battery varies, it is possible to equalize the capacity of each storage battery so that the times when the remaining capacity of each storage battery becomes zero at the time of discharging the battery assembly are close to each other, thereby effectively extending the continuous operating time of the battery assembly.
(15) In the above storage battery management device, the voltage equalization control unit may set a sign inversed value of the difference between the FCC of the target storage battery and the average FCC as the second capacity difference. According to this storage battery management device, even if the FCC of each storage battery varies, it is possible to equalize the capacity of each storage battery so that the remaining capacity of each storage battery becomes zero almost simultaneously at the time of discharge of the battery assembly, thereby extremely effectively extending the continuous operating time of the battery assembly.
(16) The above storage battery management device may further include an SOH estimation unit that estimates the SOH of each of the plurality of storage batteries, and the target voltage calculation unit may correct the internal resistance of the target storage batteries based on the SOH of the target storage batteries estimated by the SOH estimation unit, and set the target voltage based on the corrected internal resistance. According to this storage battery management device, it is possible to accurately set the target voltages based on the internal resistance corrected according to the SOH of each storage battery, and more accurately equalize the capacity of each storage battery in the voltage equalization process, thereby effectively extending the continuous operating time of the battery assembly.
(17) The above storage battery management device may further include a history unit that records the history of the current integrated amount of charge or discharge obtained by the coulomb counting processing unit and the integrated time of the charge or discharge, and the target voltage calculation unit may calculate the number of charge/discharge cycles based on the history recorded in the history unit, correct the internal resistance of the target storage battery based on the number of charge/discharge cycles, and set the target voltage based on the corrected internal resistance. According to this storage battery management device, it is possible to accurately set the target voltages based on the internal resistance corrected according to the number of charge-discharge cycles of each storage battery, and more accurately equalize the capacity of each storage battery in the voltage equalization process, thereby effectively extending the continuous operating time of the battery assembly.
(18) The above storage battery management device may further include a communication unit for communicating with the outward, and the history recorded in the history unit may be updatable via the communication unit. According to this storage battery management device, even if, e.g., the storage battery is replaced, it is possible to correct the internal resistance based on the number of charge/discharge cycles calculated based on the externally updated history of the storage battery to accurately set the target voltage based on the corrected internal resistance, and more accurately equalize the capacity of each storage battery in the voltage equalization process, thereby effectively extending the continuous operating time of the battery assembly.
(19) The above storage battery management device may further include a battery temperature measuring unit that measures the temperature of at least one of the plurality of storage batteries and a recording unit having previously recorded table data in which battery voltage, battery temperature, and battery internal resistance are associated with each other, and the internal resistance estimation unit may refer to the table data and estimate the internal resistance based on the average voltage and the battery temperature. According to this storage battery management device, it is possible to accurately estimate the internal resistance of the storage batteries, and as a result, accurately set the target voltages of each storage battery, and accurately equalize the capacity of each storage battery in the voltage equalization process, thereby effectively extending the continuous operating time of the battery assembly.
(20) In the above storage battery management device, if the average voltage is within the plateau region of the target storage battery, when the voltage of the target storage battery reaches the target voltage during the constant current control, the voltage equalization control unit may identify a capacity difference between the capacity of the target storage batteries calculated by the coulomb counting processing unit and the average capacity, and stop the constant current control if the capacity difference is smaller than the first capacity difference. According to this storage battery management device, it is possible to promptly stop the constant current control when the capacity of each storage battery is sufficiently equalized by the constant current control referring to the target voltage, thereby reducing the processing time.
(21) In the above storage battery management device, if the average voltage is not within the plateau region of the target storage battery, the voltage equalization control unit may stop the constant current control when the voltage of the target storage battery reaches the target voltage during the constant current control. According to this storage battery management device, in a case where the capacity of each storage battery can be sufficiently equalized by the constant current control referring to the target voltage since the average voltage is outside the plateau region, it is possible to promptly stop the constant current control without calculating the capacity difference between the storage batteries when the target storage battery reaches the target voltage during the voltage-referenced constant current control, thereby effectively reducing the processing time.
(22) In the above storage battery management device, the storage battery may be a battery module including a plurality of cells. According to this storage battery management device, it is possible to accurately equalize the remaining capacity of each battery module, thereby effectively extending the continuous operating time of the battery assembly.

The technology disclosed herein can be implemented in various forms, such as a storage battery management device, a battery device equipped with a storage battery management device and a battery assembly, a method for managing those devices, a computer program for implementing those methods, a non-transitory recording medium recording the computer program, among others.

### BRIEF DESCRIPTION OF DRAWINGS

FIG. 1 is an explanatory view schematically illustrating a configuration of a battery device 100 in a first embodiment.

FIG. 2 is an explanatory view schematically illustrating an SOC-OCV characteristics of a storage battery 12.

FIG. 3 is an explanatory view illustrating a circuit to equalize the voltage of a pair of storage batteries 12a, 12b extracted from a voltage equalization circuit 30.

FIG. 4 is an explanatory view illustrating an example of an internal resistance estimation table T1.

FIG. 5 is a flowchart illustrating a voltage equalization process performed in the battery device 100 of the first embodiment.

FIG. 6 is an explanatory view illustrating an example of a state of each of the storage batteries 12a, 12b during the voltage equalization process in the first embodiment.

FIG. 7 is an explanatory view illustrating an example of a state of each of the storage batteries 12a, 12b during the voltage equalization process in the first embodiment.

FIG. 8 is an explanatory view illustrating an example of a state of each of the storage batteries 12a, 12b during the voltage equalization process in the first embodiment.

FIG. 9 is an explanatory view illustrating an example of a state of each of the storage batteries 12a, 12b during the voltage equalization process in a modification of the first embodiment.

FIG. 10 is an explanatory view illustrating an example of a state of each of the storage batteries 12a, 12b during the voltage equalization process in a modification of the first embodiment.

FIG. 11 is an explanatory view schematically illustrating a configuration of a battery device 100A in a second embodiment.

FIG. 12 is a flowchart illustrating a voltage equalization process performed in the battery device 100A of the second embodiment.

FIG. 13 is an explanatory view schematically illustrating a configuration of a battery device 100B of a third embodiment.

FIG. 14 is an explanatory view schematically illustrating an operation of the constant current control when one storage battery 12a among a plurality of storage batteries 12 is a target storage battery 12x.

FIG. 15 is a flowchart illustrating a voltage equalization process performed in the battery device 100B of the third embodiment.

### DESCRIPTION OF EMBODIMENTS

### A. First Embodiment

A-1. Configuration of Battery Device 100:

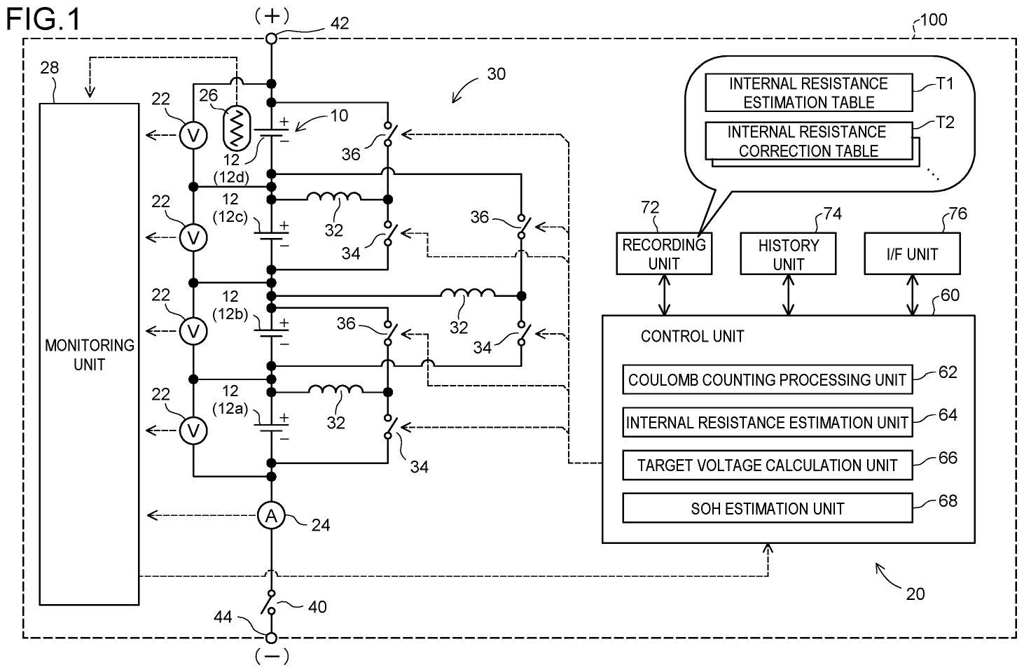

FIG. 1 is an explanatory view schematically illustrating a configuration of a battery device 100 in a first embodiment. The battery device 100 includes a battery assembly 10 and a storage battery management device 20.

The battery assembly 10 has a configuration in which a plurality of storage batteries 12 are connected in series. In this embodiment, the battery assembly 10 consists of four storage batteries 12 (12a, 12b, 12c, 12d). The battery assembly 10 is connected to a load and an external power source, not shown, via a positive terminal 42 and a negative terminal 44.

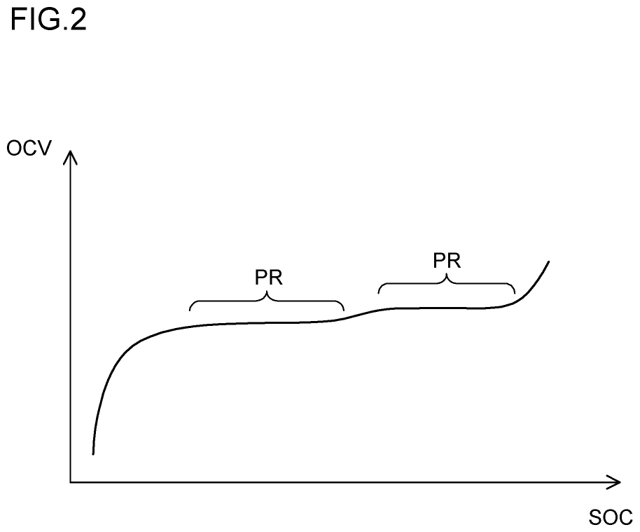

Each of the storage batteries 12 constituting the battery assembly 10 is a storage battery having SOC-OCV characteristics including a plateau region PR. FIG. 2 is an explanatory view schematically illustrating an SOC-OCV characteristics of the storage battery 12. The plateau region PR is a region where the curve representing the SOC-OCV characteristics is almost flat, or more specifically, where the absolute value of the amount of change in OCV relative to the amount of change in SOC is 2 mV/% or less. Examples of the storage battery 12 having SOC-OCV characteristics with the plateau region PR may include an iron phosphate lithium-ion battery.

The storage battery management device 20 is a device for managing the battery device 100 including the battery assembly 10. The storage battery management device 20 includes a voltmeter 22, an ammeter 24, a thermometer 26, a monitoring unit 28, a voltage equalization circuit 30, a line switch 40, a control unit 60, a recording unit 72, a history unit 74, and an interface (I/F) unit 76.

One voltmeter 22 is provided for each storage battery 12. Each voltmeter 22 is connected in parallel to each storage battery 12, measures the voltage of each storage battery 12, and outputs a signal indicating the measured voltage to the monitoring unit 28. The ammeter 24 is connected in series to the battery assembly 10. The ammeter 24 measures the current flowing through the battery assembly 10 and outputs a signal indicating the measured current to the monitoring unit 28. The thermometer 26 is located near the battery assembly 10 (e.g., near the storage battery 12d). The thermometer 26 measures the temperature of the battery assembly 10 (each storage battery 12) and outputs a signal indicating the temperature measurement value to the monitoring unit 28. Based on the signals received from the voltmeter 22, the ammeter 24, and the thermometer 26, the monitoring unit 28 outputs signals indicating the voltage of each storage battery 12, the current flowing through the battery assembly 10, and the temperature of the battery assembly 10 (each storage battery 12) to the control unit 60. The voltmeter 22 and the monitoring unit 28 are examples of the voltage measuring unit, the ammeter 24 and the monitoring unit 28 are examples of the current measuring unit, and the thermometer 26 and the monitoring unit 28 are examples of the battery temperature measuring unit.

The voltage equalization circuit 30 is a circuit that performs constant current control to reduce the voltage difference among the plurality of storage batteries 12 constituting the battery assembly 10 by transferring electric charge among the storage batteries 12. In other words, the voltage equalization circuit 30 is a circuit for executing an active voltage equalization. The voltage equalization circuit 30 includes a coil 32, a first switch 34, and a second switch 36, and is configured to execute voltage equalization for each pair of two mutually adjacent storage batteries 12. In other words, in this embodiment, since the battery assembly 10 includes four storage batteries 12, the voltage equalization circuit 30 is configured to be able to perform voltage equalization for each of the three pairs of storage batteries 12 (a pair of storage batteries 12a, 12b, a pair of storage batteries 12b, 12c, and a pair of storage batteries 12c, 12d). For example, MOSFETs or relays may be used as the first switch 34 and the second switch 36.

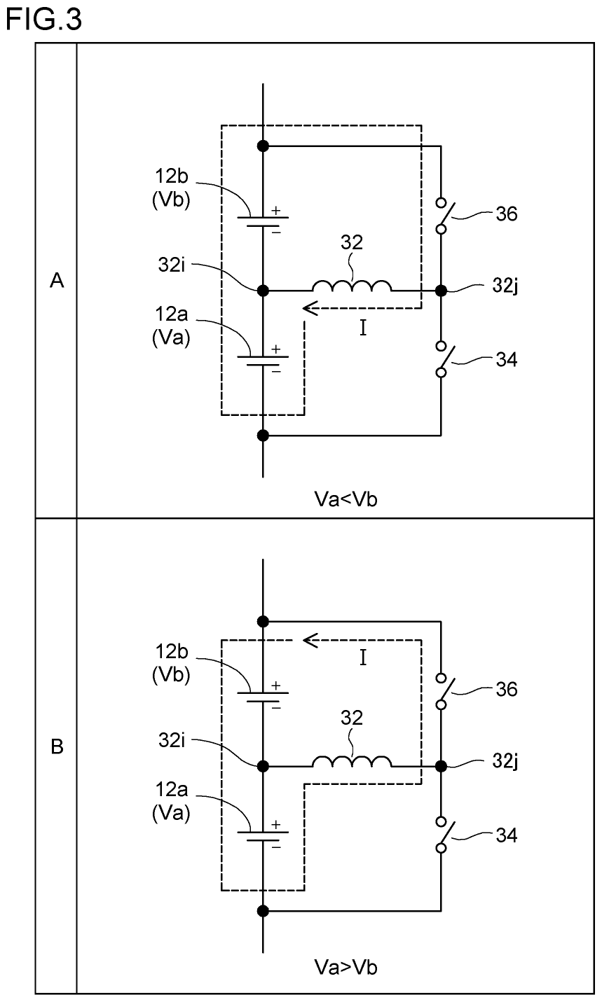

FIG. 3 is an explanatory view illustrating a circuit to equalize the voltage of a pair of storage batteries 12a, 12b extracted from a voltage equalization circuit 30. As shown in columns A and B of FIG. 3, one end 32i of the coil 32 is connected to a connection point between the positive terminal of one storage battery 12a and the negative terminal of the other storage battery 12b. The first switch 34 is connected between the negative terminal of the one storage battery 12a and the other end 32j of the coil 32. The second switch 36 is connected between the positive terminal of the other storage battery 12b and the other end 32j of the coil 32. The control unit 60 controls the on/off of the first switch 34 and the second switch 36 by a predetermined modulation method (e.g., pulse width modulation (PWM)) to perform constant current control, thereby causing electric charge to be transferred between the storage batteries 12 via the coil 32. Column A of FIG. 3 shows a state in which the voltage Vb of the storage battery 12b is greater than the voltage Va of the storage battery 12a, and voltage equalization is being performed by transferring electric charge from the storage battery 12b to the storage battery 12a via the coil 32. Column B of FIG. 3 shows a state in which the voltage Va of the storage battery 12a is greater than the voltage Vb of storage battery 12b, and voltage equalization is being performed by transferring electric charge from the storage battery 12a to the storage battery 12b via the coil 32. Although FIG. 3 shows only the circuit to equalize the voltage of the pair of storage batteries 12a, 12b extracted from the voltage equalization circuit 30, the circuits to equalize the voltage of other pairs (the pair of storage batteries 12b, 12c and the pair of storage batteries 12c, 12d) have the same configuration.

The line switch 40 (FIG. 1) is provided between the battery assembly 10 and the negative terminal 44. The line switch 40 is controlled on and off by the control unit 60 to open and close the connection between the battery assembly 10 and the load/external power source.

The control unit 60 is configured by using, e.g., a CPU, a multi-core CPU, and a programmable device (such as field programmable gate array (FPGA) and programmable logic device (PLD)) to control the operation of the storage battery management device 20. The control unit 60 has functions as a coulomb counting processing unit 62, an internal resistance estimation unit 64, a target voltage calculation unit 66, and an SOH estimation unit 68. The functions of each of these units are described in conjunction with the description of the voltage equalization process below. The control unit 60 is an example of the voltage equalization control unit.

The recording unit 72 is composed of, e.g., ROM, RAM, a hard disk drive (HDD), and is used to store various programs and data, or as a work area or data storage area when executing various processes. For example, the recording unit 72 stores a computer program for executing the voltage equalization process described below. The computer program is provided, e.g., in the form of a computer-readable recording medium (not shown) such as a CD-ROM, DVD-ROM, and USB memory, and is stored in the recording unit 72 by being installed in the battery device 100.

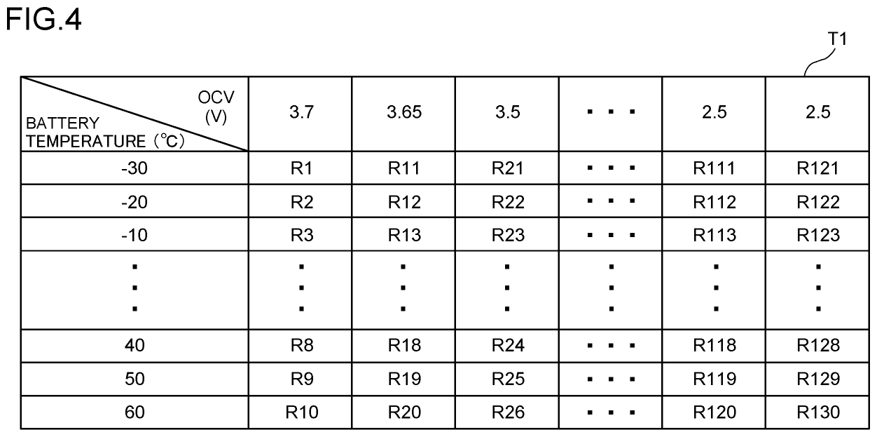

The recording unit 72 also stores an internal resistance estimation table T1 and an internal resistance correction table T2. The internal resistance estimation table T1 is a table used to estimate the internal resistance of each of the storage batteries 12. FIG. 4 is an explanatory view illustrating an example of the internal resistance estimation table T1. The internal resistance estimation table T1 is a table that associates battery voltage (more precisely, OCV), battery temperature, and battery internal resistance. The relationship defined in the internal resistance estimation table T1 is experimentally determined in advance. By referring to the internal resistance estimation table T1, the battery internal resistance can be estimated based on the battery voltage and battery temperature of each storage battery 12. In FIG. 4, the battery internal resistance is indicated as R1, R2, . . . , but the internal resistance estimation table T1 actually defines the numerical value of the battery internal resistance.

The internal resistance correction table T2 (FIG. 1) recorded in the recording unit 72 is a table used to correct the battery internal resistance specified by the internal resistance estimation table T1. In this embodiment, the internal resistance correction table T2 defines the relationship between the SOH (State of Health) of the battery and the correction amount of internal resistance, and the relationship between the number of charge/discharge cycles and the correction amount of internal resistance. The relationship specified in the internal resistance correction table T2 is experimentally determined in advance. This relationship is such that as the SOH of the battery decreases (the degree of degradation increases), the battery internal resistance is corrected to a higher value, and as the number of charge/discharge cycles of the battery increases, the battery internal resistance is corrected to a higher value. By referring to the internal resistance correction table T2, it is possible to correct the battery internal resistance based on the SOH of each storage battery 12 and the number of charge/discharge cycles.

The history unit 74 is composed of, e.g., ROM, RAM, and a hard disk drive (HDD), and records various histories related to the battery device 100. Such history includes, e.g., the integrated time of the charge and discharge. The interface unit 76 communicates with other devices by a wired or wireless means. For example, the history recorded in the history unit 74 is updated by communication with other devices via the interface unit 76. The interface unit 76 is an example of the communication unit.

A-2. Voltage Equalization Process:

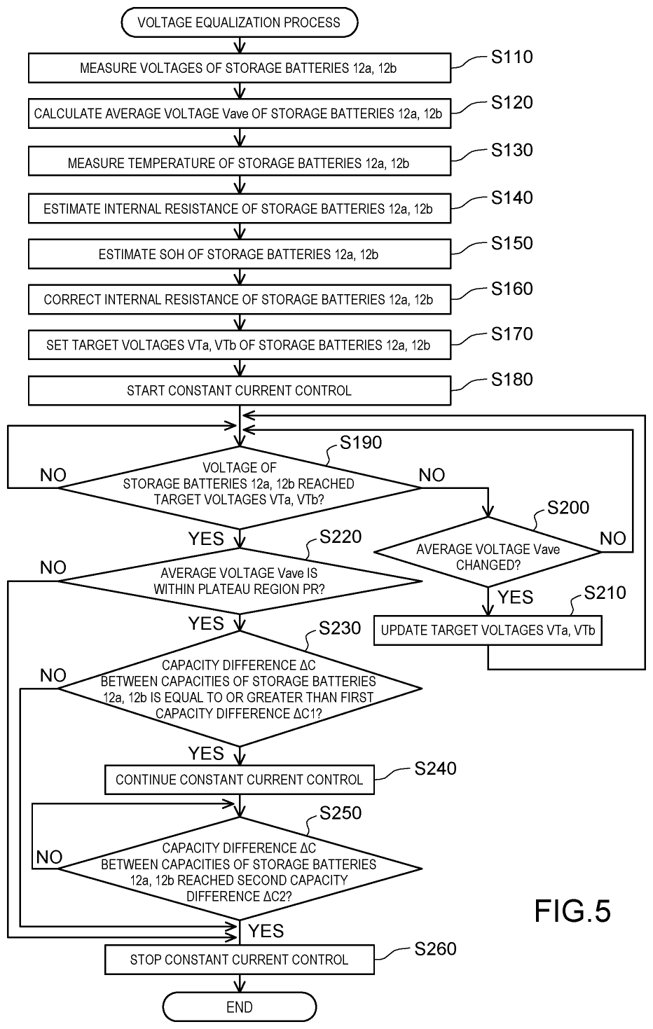

Next, the voltage equalization process executed by the storage battery management device 20 in the battery device 100 of the first embodiment will be described. FIG. 5 is a flowchart illustrating a voltage equalization process performed in the battery device 100 of the first embodiment. The voltage equalization process of the first embodiment is a process that executes constant current control to reduce the voltage difference among the plurality of storage batteries 12 constituting the battery assembly 10 by transferring electric charge among the plurality of storage batteries 12. The voltage equalization process is started, e.g., automatically when the voltage difference among the plurality of storage batteries 12 constituting the battery assembly 10 is detected to be larger than a predetermined threshold value, or in response to an instruction from the administrator.

The following is a description of the voltage equalization process performed on a pair of storage batteries of the storage battery 12a with relatively high voltage (hereinafter also referred to as the “discharge-side storage battery 12a”) and the storage battery 12b with relatively low voltage (hereinafter referred to as the “charge-side storage battery 12b”) among the plurality of storage batteries 12 constituting the battery assembly 10. The discharge-side storage battery 12a is an example of the first storage battery and the charge-side storage battery 12b is an example of the second storage battery.

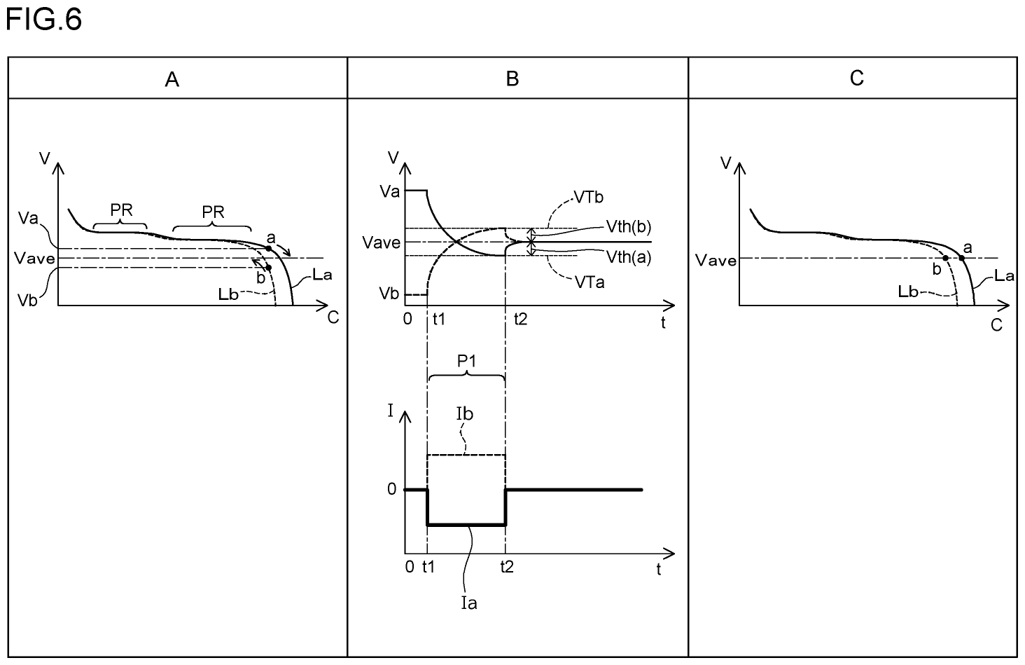

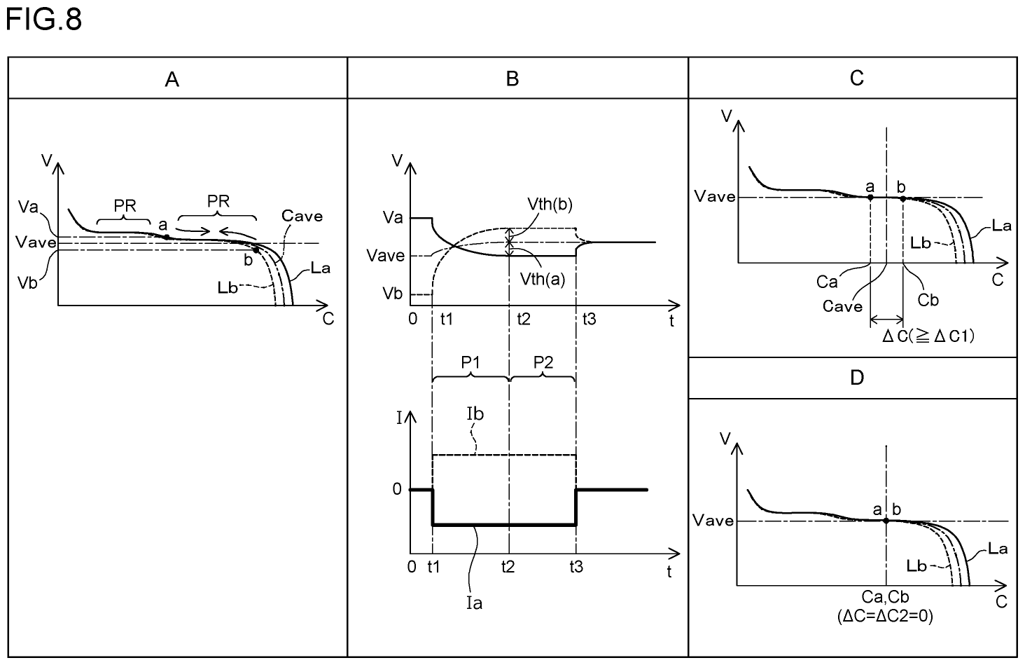

FIGS. 6 to 8 are explanatory views illustrating examples of a state of each of the storage batteries 12a, 12b during the voltage equalization process in the first embodiment. In each of FIGS. 6 to 8, column A shows a state of voltage V and discharge capacity C of storage batteries 12a, 12b at the start of the voltage equalization process, column B shows the change over time of voltage V and current I of storage batteries 12a, 12b during the voltage equalization process, and column C shows a state of voltage V and discharge capacity C of storage batteries 12a, 12b at the end of the voltage equalization process. However, for FIG. 8, column C shows a state of voltage V and discharge capacity C of storage batteries 12a, 12b during the voltage equalization process (time t2), and column D shows a state of voltage V and discharge capacity C of storage batteries 12a, 12b at the end of the voltage equalization process.

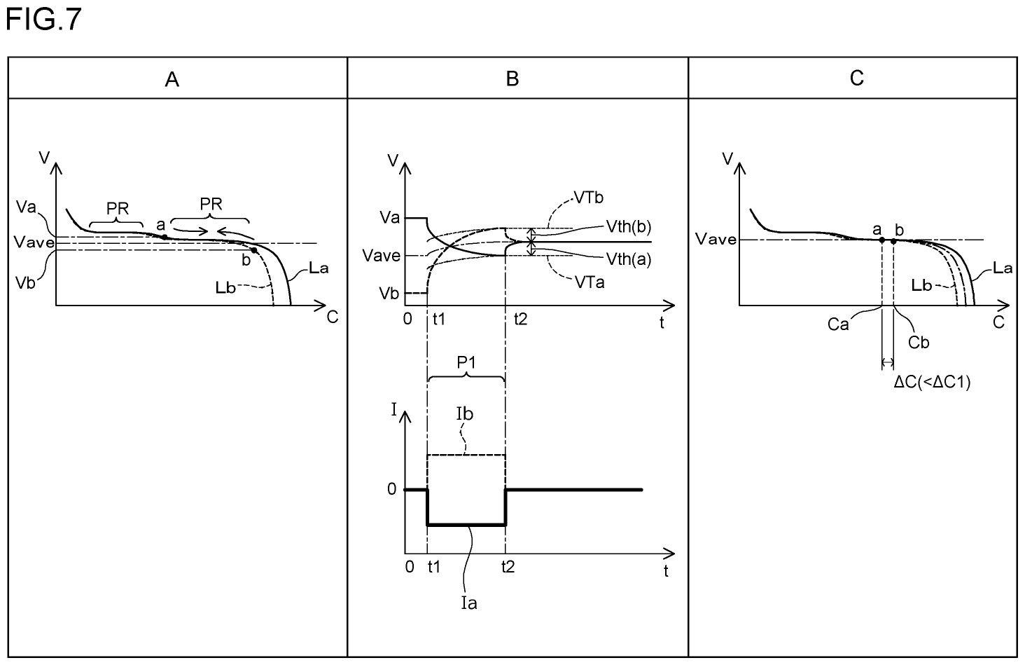

As described in detail below, FIGS. 6 to 8 show examples in which the voltage V and the discharge capacity C of the storage batteries 12a, 12b differ from each other at the start of, during, and/or at the end of the voltage equalization process. For example, in the example shown in FIG. 6, at the start of the voltage equalization process (see FIG. 6, column A), both the discharge-side storage battery 12a and charge-side storage battery 12b have relatively large changes in voltage relative to changes in capacity. On the other hand, in the examples shown in FIGS. 7 and 8, at the start of the voltage equalization process (see FIGS. 7 and 8, column A), the change in voltage relative to the change in capacity is relatively large in the charge-side storage battery 12b, while the change in voltage relative to the change in capacity is relatively small in the discharge-side storage battery 12a. In the examples of FIGS. 6 to 8, as shown in columns A and C of the respective drawings, the curves La and Lb, which show the relationship between the discharge capacity C and the voltage V of the storage batteries 12a, 12b, respectively, do not match. In other words, storage battery 12a and storage battery 12b are storage batteries whose characteristics regarding the relationship between discharge capacity C and voltage V differ from each other. Such differences are caused, e.g., by differences in initial performance and the degree of degradation.

When the voltage equalization process (FIG. 5) is started, the control unit 60 (FIG. 1) of the storage battery management device 20 measures the voltages of the storage batteries 12a, 12b based on signals input from the monitoring unit 28 (S110). It should be noted that the measurement of the voltage of the storage batteries 12a, 12b is continuously performed during the voltage equalization process. Next, the control unit 60 calculates the average voltage Vave, which is the average value of the voltages of the storage batteries 12a, 12b (S120). The control unit 60 also measures the temperature of the storage batteries 12a, 12b based on signals input from the monitoring unit 28 (S130).

Next, the internal resistance estimation unit 64 (FIG. 1) of the control unit 60 estimates the internal resistance of the storage batteries 12a, 12b (S140). In this embodiment, the internal resistance estimation unit 64 refers to the internal resistance estimation table T1 (FIG. 4) described above, which associates the battery voltage, the battery temperature, and the battery internal resistance to estimate the internal resistance of the storage batteries 12a, 12b based on the voltage and temperature of the storage batteries 12a, 12b measured in S110 and S130. The method of estimating the internal resistance of the storage batteries 12a, 12b is not limited to this, and other known estimation methods may be employed.

Next, the SOH estimation unit 68 (FIG. 1) of the control unit 60 estimates the SOH of the storage batteries 12a, 12b (S150). In this method, when the voltage equalization process is not executed and during the voltage equalization process, the coulomb counting processing unit 62 (FIG. 1) of the control unit 60 integrates the current measured by the ammeter 24 and the monitoring unit 28 with the current during the constant current control in the voltage equalization process to calculate the capacity of each storage battery 12. The SOH estimation unit 68 estimates the SOH of each of the storage batteries 12a, 12b based on the charge transfer amount (charge transfer amount measurement value) between the predetermined SOCs for each of the storage batteries 12a, 12b obtained by the coulomb counting processing unit 62 and the charge transfer amount (charge transfer amount initial value) between the predetermined SOCs for a new storage battery 12 recorded in the recording unit 72 in advance. In other words, the SOH estimation unit 68 calculates the ratio of the charge transfer amount measurement value to the charge transfer amount initial value as the SOH of the storage batteries 12a, 12b. The method of estimating the SOH of the storage batteries 12a, 12b is not limited to this, and other known estimation methods may be employed.

Next, the target voltage calculation unit 66 (FIG. 1) of the control unit 60 corrects the internal resistance of the storage batteries 12a, 12b estimated in S140 based on the SOH of the storage batteries 12a, 12b estimated in S150 (S160). In this embodiment, the target voltage calculation unit 66 corrects the internal resistance of the storage batteries 12a, 12b based on the SOH of the storage batteries 12a, 12b by referring to the internal resistance correction table T2 (FIG. 1) described above, which associates the SOH of the batteries and the correction amount of the internal resistance. In this correction, e.g., as the SOH of the batteries decreases (the degree of deterioration increases), the internal resistance of the batteries is corrected to a higher value.

Instead of or in addition to the correction of the internal resistance of the storage batteries 12a, 12b in S160, the internal resistance may be corrected based on the number of charge/discharge cycles of the storage batteries 12a, 12b. For example, the internal resistance of the storage batteries 12a, 12b may be corrected based on the number of charge/discharge cycles by recording, in the history unit 74 (FIG. 1), the history of the current integrated amount of charge or discharge obtained by the coulomb counting processing unit 62 and the integrated time of the charge or discharge, and calculating, by the target voltage calculation unit 66, the number of charge/discharge cycles of the storage batteries 12a, 12b based on the history recorded in the history unit 74 and referring to the internal resistance correction table T2 described above, which specifies the relationship between the number of charge/discharge cycles and the correction amount of the internal resistance. In this correction, e.g., as the number of charge/discharge cycles of the battery increases, the battery internal resistance is corrected to a higher value.

Next, the target voltage calculation unit 66 sets the target voltages of the storage batteries 12a, 12b (the target voltage VTa of the storage battery 12a and the target voltage VTb of the storage battery 12b) based on the average voltage Vave of the storage batteries 12a, 12b calculated in S120 and the internal resistance of the storage batteries 12a, 12b estimated in S140 and corrected in S160 (S170). More specifically, for the discharge-side storage battery 12a, the value obtained by subtracting an adjustment voltage Vth(a), which is set based on the internal resistance of the discharge-side storage battery 12a, from the average voltage Vave is set as the target voltage VTa (see, e.g., FIG. 6, column B) (i.e., VTa=Vave−Vth(a)). For the charge-side storage battery 12b, the value obtained by adding an adjustment voltage Vth(b), which is set based on the internal resistance of the charge-side storage battery 12b, to the average voltage Vave is set as the target voltage VTb (see, e.g., FIG. 6, column B) (i.e., VTb=Vave+Vth(b)). The relationship between the internal resistance of the storage battery 12 and each adjustment voltage is determined experimentally in advance, e.g., as the internal resistance of the storage battery 12 increases, the adjustment voltage is set to a higher value. The method of setting the target voltages VTa and VTb is not limited to this, and other known setting methods (e.g., the method described in JP 2014-75953 A) may be employed. The target voltage VTa of the discharge-side storage battery 12a is an example of the first target voltage, and the target voltage VTb of the charge-side storage battery 12b is an example of the second target voltage.

Next, the control unit 60 controls the voltage equalization circuit 30 (FIG. 1) to start constant current control for voltage equalization (S180). In this constant current control, the first switch 34 and the second switch 36 constituting the voltage equalization circuit 30 are controlled on and off to transfer the electric charge from the discharge-side storage battery 12a to the charge-side storage battery 12b via the coil 32 so that the voltages of the storage batteries 12a, 12b approach their respective target voltages VTa and VTb. For example, as shown in column B of FIG. 6, when constant current control is started at time t1, the current Ia flowing through the discharge-side storage battery 12a takes a negative constant value and the current 1b flowing through the charge-side storage battery 12b takes a positive constant value, resulting in the voltage Va of the discharge-side storage battery 12a decreasing to approach the target voltage VTa and the voltage Vb of the charge-side storage battery 12b increasing to approach the target voltage VTb. The constant current control performed here is referred to as voltage-referenced constant current control P1 to distinguish it from the capacity-referenced constant current control P2 described below.

After the start of constant current control, the control unit 60 monitors whether at least one of the voltages Va of the discharge-side storage battery 12a and the voltage Vb of the charge-side storage battery 12b has reached the respective target voltages VTa and VTb (S190), and whether the average voltage Vave has changed (S200). In the present embodiment, the average voltage Vave has changed means that the average voltage Vave has changed by a predetermined threshold value or more. If the average voltage Vave has changed (S200: YES), the target voltage calculation unit 66 updates the target voltages VTa and VTb based on the changed average voltage Vave (S210).

For example, in the example shown in FIG. 6, as described above, at the start of the voltage equalization process, both the discharge-side storage battery 12a and the charge-side storage battery 12b are in a state where the voltage change relative to the capacity change is relatively large (see FIG. 6, column A). Therefore, when the constant current control is started and electric charge is transferred from the discharge-side storage battery 12a to the charge-side storage battery 12b, the voltage Va of the discharge-side storage battery 12a decreases relatively largely and the voltage Vb of the charge-side storage battery 12b increases relatively largely, resulting in the average voltage Vave being maintained almost constant (see FIG. 6, column B). In contrast, in the examples shown in FIGS. 7 and 8, as described above, at the start of the voltage equalization process, the voltage of the charge-side storage battery 12b has a relatively large change in voltage relative to the change in capacity, while the voltage of the discharge-side storage battery 12a has a relatively small change in voltage relative to the change in capacity (see FIG. 7 and FIG. 8, column A). Therefore, when constant current control is started and electric charge is transferred from the discharge-side storage battery 12a to the charge-side storage battery 12b, the voltage Vb of the charge-side storage battery 12b increases relatively largely, while the voltage Va of the discharge-side storage battery 12a is maintained almost constant, resulting in a relatively large change in the average voltage Vave (see FIG. 7 and FIG. 8, column B). In this case, the target voltages VTa and VTb are updated in S210.

If at least one of the voltages Va of the discharge-side storage battery 12a and the voltage Vb of the charge-side storage battery 12b reaches the respective target voltages VTa, VTb (S190: YES) during execution of the constant current control (voltage-referenced constant current control P1), the control unit 60 determines whether the average voltage Vave is within the plateau region PR for at least one of the discharge-side storage battery 12a and the charge-side storage battery 12b (S220). This determination is made to determine whether the remaining capacities of the storage batteries 12a, 12b can be accurately equalized by constant current control (voltage-referenced constant current control P1) referring to the target voltages VTa and VTb, as explained below.

In the example of FIG. 6, the average voltage Vave is not within the plateau region PR of the storage batteries 12a, 12b (see FIG. 6, column A). In this case, the remaining capacity of the storage batteries 12a, 12b can be accurately equalized by constant current control (voltage-referenced constant current control P1) referring to the target voltages VTa, VTb, because the change in voltage relative to the change in capacity of the storage batteries 12a, 12b is relatively large near the average voltage Vave. Therefore, if it is determined that the average voltage Vave is not within the plateau region PR (S220: NO), the control unit 60 stops the constant current control (S260). In other words, as shown in column B of FIG. 6, when at least one of the voltages Va of the discharge-side storage battery 12a and the voltage Vb of the charge-side storage battery 12b reaches the respective target voltages VTa and VTb at time t2, the constant current control is stopped and the currents Ia and Ib flowing through the storage batteries 12a, 12b become zero. Thereafter, the internal resistance of storage batteries 12a, 12b relaxes, and the voltage Va of the discharge-side storage battery 12a and the voltage Vb of the charge-side storage battery 12b converge to the average voltage Vave. As a result, the remaining capacities of storage batteries 12a, 12b are accurately equalized, as shown in column C of FIG. 6.

On the other hand, in the examples in FIGS. 7 and 8, the average voltage Vave is within the plateau region PR of the storage batteries 12a, 12b (see FIGS. 7 and 8, column A). In this case, since the change in voltage with respect to the change in capacity of the storage batteries 12a, 12b is relatively small near the average voltage Vave, the remaining capacity of the storage batteries 12a, 12b cannot be accurately equalized by constant current control (voltage-referenced constant current control P1) referring to the target voltage VTa, VTb. Therefore, in such cases, the following process is performed to accurately equalize the remaining capacities of storage batteries 12a, 12b.

That is, upon determining that the average voltage Vave is within the plateau region PR (S220: YES), the control unit 60 identifies the capacity difference ΔC between the capacity Ca of the discharge-side storage battery 12a and the capacity Cb of the charge-side storage battery 12b calculated by the Coulomb counting processing unit 62 (ΔC=Ca−Cb) to judge whether the capacity difference ΔC is equal to or greater than the predetermined first capacity difference ΔC1(S230). If it is determined that the capacity difference ΔC is smaller than the first capacity difference ΔC1 (S230: NO), the control unit 60 stops the constant current control (S260). In the example of FIG. 7, when at least one of the voltage Va of the discharge-side storage battery 12a and the voltage Vb of the charge-side storage battery 12b reaches the respective target voltages VTa and VTb at time t2, the capacity difference ΔC is relatively small (smaller than the first capacity difference ΔC1) as shown in column C of FIG. 7. Therefore, at time t2, the constant current control is stopped and the currents Ia and Ib flowing through the storage batteries 12a, 12b become zero. Thereafter, the internal resistance of storage batteries 12a, 12b relaxes, and the voltage Va of discharge-side storage battery 12a and the voltage Vb of charge-side storage battery 12b converge to the average voltage Vave. As a result, the remaining capacities of storage batteries 12a, 12b are more accurately equalized.

On the other hand, if it is determined that the capacity difference ΔC is equal to or greater than the first capacity difference ΔC1 (S230: YES), the control unit 60 continues the constant current control (S240) and monitors whether the capacity difference ΔC has reached the predetermined second capacity difference ΔC2 (S250). The absolute value of the second capacity difference ΔC2 is smaller than the absolute value of the first capacity difference ΔC1. The value of the second capacity difference ΔC2 may be zero. The constant current control continued in S240 is referred to as capacity-referenced constant current control P2 to distinguish it from the voltage-referenced constant current control P1. During execution of the constant current control (capacity-referenced constant current control P2), the control unit 60 monitors the capacity difference ΔC, and stops the constant current control (S260) when the capacity difference ΔC reaches the second capacity difference ΔC2 (S250: YES).

In the example of FIG. 8, when at least one of the voltage Va of the discharge-side storage battery 12a and the voltage Vb of the charge-side storage battery 12b reaches the respective target voltages VTa and VTb at time t2, the capacity difference Δ C is relatively large (greater than the first capacity difference ΔC1), as shown in column C of FIG. 8. Therefore, constant current control (capacity-referenced constant current control P2) is continued after time t2. Thereafter, at time t3, when the capacity difference ΔC reaches the second capacity difference ΔC2, the constant current control is stopped and the currents Ia and Ib flowing through the storage batteries 12a, 12b become zero. In the example of FIG. 8, as shown in columns C and D of FIG. 8, at time t3, both the capacity Ca of the discharge-side storage battery 12a and the capacity Cb of the charge-side storage battery 12b are equal to the average capacity Cave of the capacities Ca and Cb at time t2. In other words, in the example of FIG. 8, the second capacity difference ΔC2 is zero. Thereafter, the internal resistance of storage batteries 12a, 12b relaxes, and the voltage Va of discharge-side storage battery 12a and the voltage Vb of charge-side storage battery 12b converge to the average voltage Vave. As a result, the remaining capacities of storage batteries 12a, 12b are accurately equalized.

In any of the above cases, when the constant current control is stopped (S260), the voltage equalization process is completed.

A-3. Effects of the First Embodiment:

As explained above, the storage battery management device 20 of the first embodiment is a device for managing a battery assembly 10 in which the storage battery 12a (discharge-side storage battery 12a) and the storage battery 12b (charge-side storage battery 12b) having SOC-OCV characteristics including a plateau region PR are connected in series. The storage battery management device 20 includes the voltmeter 22, the ammeter 24, the monitoring unit 28, the voltage equalization circuit 30, the coulomb counting processing unit 62, the internal resistance estimation unit 64, the target voltage calculation unit 66, and the control unit 60. The voltmeter 22 and the monitoring unit 28 measure the voltage of the storage batteries 12a, 12b. The ammeter 24 and monitoring unit 28 measure the current flowing through the battery assembly 10. The voltage equalization circuit 30 performs constant current control to reduce the difference between the voltage Va of the discharge-side storage battery 12a and the voltage Vb of the charge-side storage battery 12b by transferring electric charge from the discharge-side storage battery 12a to the charge-side storage battery 12b. The coulomb counting processing unit 62 integrates the current measured by the ammeter 24 and the monitoring unit 28 with the current during the above constant current control to calculate the capacities of the storage batteries 12a, 12b. The internal resistance estimation unit 64 estimates the internal resistance of the storage batteries 12a, 12b. The target voltage calculation unit 66 sets the target voltage VTa of the discharge-side storage battery 12a and the target voltage VTb of the charge-side storage battery 12b based on the average voltage Vave of the voltage Va of the discharge-side storage battery 12a and the voltage Vb of the charge-side storage battery 12b measured by the voltmeter 22 and the monitoring unit 28, and the internal resistance estimated by the internal resistance estimation unit 64. The control unit 60 controls the voltage equalization circuit 30 to cause the voltage equalization circuit 30 to perform the above constant current control.

If the average voltage Vave is within the plateau region PR for at least one of the discharge-side storage battery 12a and the charge-side storage battery 12b (S220: YES in FIG. 5), when the voltage Va of the discharge-side storage battery 12a reaches the target voltage VTa or the voltage Vb of the charge-side storage battery 12b reaches the target voltage VTb during the constant current control (voltage-referenced constant current control P1) described above, the control unit 60 identifies the capacity difference ΔC between the capacity Ca of the discharge-side storage battery 12a and the capacity Cb of the charge-side storage battery 12b calculated by the coulomb counting processing unit 62 (ΔC=Ca−Cb), continues the constant current control (capacity-referenced constant current control P2) (S240) if the capacity difference ΔC is equal to or greater than the predetermined first capacity difference ΔC1 (S230: YES), and stops the constant current control (S260) when the capacity difference ΔC reaches the predetermined second capacity difference ΔC2 (S250: YES), the absolute value of the second capacity difference ΔC2 being smaller than the absolute value of the first capacity difference ΔC1.

Thus, according to the storage battery management device 20 of this embodiment, in a battery assembly 10 in which a plurality of storage batteries 12 having SOC-OCV characteristics including a plateau region PR are connected in series, even when the average voltage Vave of the two storage batteries 12a, 12b is within the plateau region PR and the constant current control (voltage-referenced constant current control P1) referring to the target voltages VTa and VTb may not be sufficient to accurately equalize the remaining capacity of each of the storage batteries 12a, 12b, by performing constant current control (capacity-referenced constant current control P2) referring to the capacity difference ΔC of the two storage batteries 12a, 12b, it is possible to accurately equalize the remaining capacity of each storage battery 12a, 12b, thereby effectively extending the continuous operating time of the battery assembly 10.

In the storage battery management device 20 of this embodiment, when there is a change in the average voltage Vave during constant current control (S200: YES in FIG. 5), the target voltage calculation unit 66 updates the target voltages VTa, VTb based on the average voltage Vave after the change (S210). Therefore, according to the storage battery management device 20 of this embodiment, even if the average voltage Vave of the two storage batteries 12a, 12b changes during the constant current control for voltage equalization, the target voltages VTa, VTb can be updated according to the change, and as a result, it is possible to accurately equalize remaining capacity of each of the storage batteries 12a, 12b in the voltage equalization process, thereby effectively extending the continuous operating time of the battery assembly 10.

The storage battery management device 20 of this embodiment further includes the SOH estimation unit 68 that estimates the SOH of the storage batteries 12a, 12b. The control unit 60 corrects (S160) the internal resistance of the storage batteries 12a, 12b based on the SOH of the storage batteries 12a, 12b estimated by the SOH estimation unit 68 (S150 in FIG. 5) and sets the target voltages VTa, VTb based on the corrected internal resistance (S170). Therefore, according to the storage battery management device 20 of this embodiment, it is possible to accurately set the target voltages VTa, VTb based on the internal resistance corrected according to the SOH of each storage battery 12a, 12b, and more accurately equalize the capacity of each storage battery 12a, 12b in the voltage equalization process, thereby effectively extending the continuous operating time of the battery assembly 10.

The storage battery management device 20 of this embodiment may further include the history unit 74 that records the history of the current integrated amount of charge or discharge obtained by the coulomb counting processing unit 62 and the integrated time of the charge or discharge. The target voltage calculation unit 66 may calculate the number of charge/discharge cycles based on the history recorded in the history unit 74, correct the internal resistance of the storage batteries 12a, 12b based on the number of charge/discharge cycles, and set the target voltages VTa, VTb based on the corrected internal resistance. In this way, it is possible to accurately set the target voltages VTa, VTb based on the internal resistance corrected according to the number of charge-discharge cycles of each storage battery 12a, 12b, and more accurately equalize the capacity of each storage battery 12a, 12b in the voltage equalization process, thereby effectively extending the continuous operating time of the battery assembly 10.

The storage battery management device 20 of this embodiment is further includes the interface unit 76 that communicates with the outward, and the history recorded in the history unit 74 is updatable via the interface unit 76. Therefore, according to the storage battery management device 20 of this embodiment, even if, e.g., the storage battery 12 is replaced, it is possible to correct the internal resistance based on the number of charge/discharge cycles calculated based on the externally updated history of the storage battery 12 to accurately set the target voltage VT based on the corrected internal resistance, and more accurately equalize the capacity of each storage battery 12 in the voltage equalization process, thereby effectively extending the continuous operating time of the battery assembly 10.

The storage battery management device 20 of this embodiment further includes the thermometer 26 and the recording unit 72. The thermometer 26 and the monitoring unit 28 measure the temperature of at least one of the storage batteries 12a, 12b. The recording unit 72 records an internal resistance estimation table T1 that associates battery voltage, battery temperature, and battery internal resistance in advance. The internal resistance estimation unit 64 estimates the internal resistance based on the average voltage Vave and the battery temperature referring to the internal resistance estimation table T1. Therefore, according to the storage battery management device 20 of this embodiment, it is possible to accurately estimate the internal resistance of the storage batteries 12a, 12b, accurately set the target voltages VTa, VTb of each storage battery 12a, 12b, and accurately equalize the capacity of each storage battery 12a, 12b in the voltage equalization process, thereby effectively extending the continuous operating time of the battery assembly 10.

Further, in this embodiment, if the average voltage Vave is within the plateau region PR for at least one of the discharge-side storage battery 12a and the charge-side storage battery 12b (S220: YES in FIG. 5), when the voltage Va of the discharge-side storage battery 12a reaches the target voltage VTa or the voltage Vb of the charge-side storage battery 12b reaches the target voltage VTb during the constant current control (voltage-referenced constant current control P1) described above, the control unit 60 identifies the capacity difference ΔC between the capacity Ca of the discharge-side storage battery 12a and the capacity Cb of the charge-side storage battery 12b calculated by the coulomb counting processing unit 62 (ΔC=Ca−Cb), and stops the constant current control (S260) when the capacity difference ΔC is smaller than the predetermined first capacity difference ΔC1 (S230: NO). Therefore, according to the storage battery management device 20 of this embodiment, it is possible to promptly stop the constant current control when the capacity of each storage battery 12a, 12b is sufficiently equalized by the constant current control (voltage-referenced constant current control P1) referring to the target voltages VTa, VTb, thereby reducing the processing time.

In this embodiment, if the average voltage Vave is not within the plateau region PR of either the discharge-side storage battery 12a or the charge-side storage battery 12b (S220: NO in FIG. 5), when the voltage Va of the discharge-side storage battery 12a reaches the target voltage VTa or the voltage Vb of the charge-side storage battery 12b reaches the target voltage VTb during the constant current control (voltage-referenced constant current control P1) described above, the control unit 60 stops the constant current control (S260). Therefore, in a case where the capacity of each storage battery 12a, 12b can be sufficiently equalized by the constant current control (voltage-referenced constant current control P1) referring to the target voltage VTa, VTb since the average voltage Vave of the two storage batteries 12a, 12b is outside the plateau region PR, the storage battery management device 20 of this embodiment is able to promptly stop the constant current control without calculating the capacity difference ΔC between the storage batteries 12 when one of the storage batteries 12 reaches the target voltage during the voltage-referenced constant current control P1, thereby effectively reducing the processing time.

A-4. Modification of the First Embodiment:

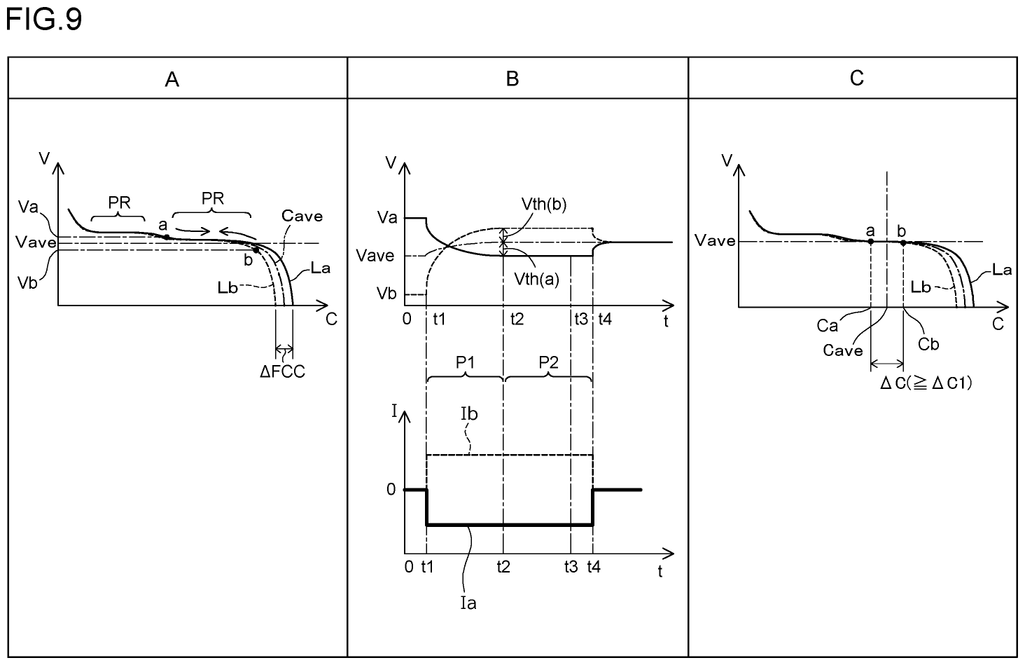

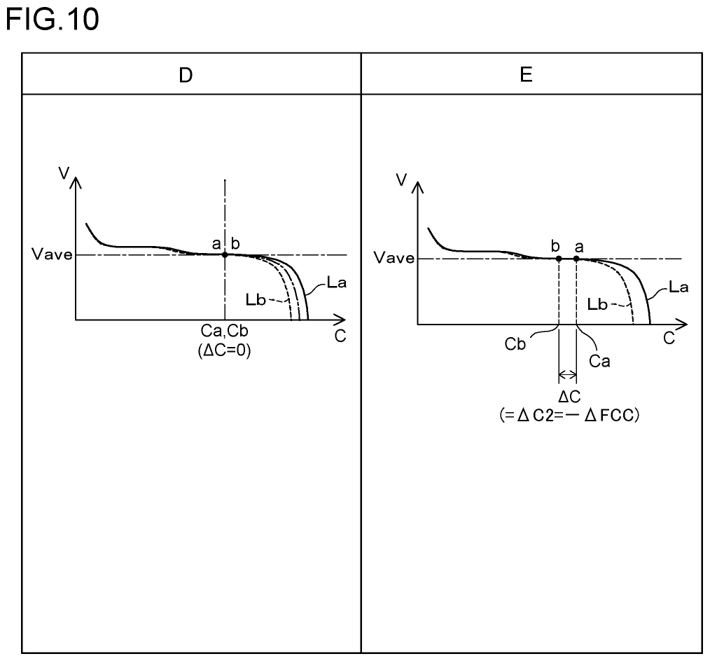

FIGS. 9 and 10 are explanatory views illustrating an example of a state of each of the storage batteries 12a, 12b during the voltage equalization process in a modification of the first embodiment. Column A of FIG. 9 shows a state of voltage V and discharge capacity C of storage batteries 12a, 12b at the start of the voltage equalization process, column B of FIG. 9 shows the change over time of voltage V and current I of storage batteries 12a, 12b during the voltage equalization process, column C of FIG. 9 shows a state of voltage V and discharge capacity C of storage batteries 12a, 12b during the voltage equalization process (time t2), column D of FIG. 10 shows a state of voltage V and discharge capacity C of storage batteries 12a, 12b during the voltage equalization process (time t3), and column E of FIG. 10 shows a state of voltage V and discharge capacity C of storage batteries 12a, 12b at the end of the voltage equalization process. In the modification shown in FIGS. 9 and 10, as in the example shown in FIG. 8, when the average voltage Vave of the storage batteries 12a, 12b is within the plateau region PR (see FIG. 9, column A) and at least one of the voltage Va of the discharge-side storage battery 12a and the voltage Vb of the charge-side storage battery 12b reaches the respective target voltage VTa and VTb at time t2, the capacity difference ΔC between the capacity Ca of the discharge-side storage battery 12a and the capacity Cb of the charge-side storage battery 12b (ΔC=Ca−Cb) is relatively large (more than the first capacity difference ΔC1) as shown in column C of FIG. 9. Therefore, constant current control (capacity-referenced constant current control P2) is continued after time t2.

In the modification shown in FIGS. 9 and 10, the second capacity difference ΔC2 for determining the stop timing of the capacity-referenced constant current control P2 is set based on the difference ΔFCC between the FCC (full charge capacity) of the discharge-side storage battery 12a and the FCC of the charge-side storage battery 12b (see FIG. 9, column A). More specifically, the sign inversed value of the difference ΔFCC(=−ΔFCC) between the FCC of the discharge-side storage battery 12a and the FCC of the charge-side storage battery 12b is set as the second capacity difference ΔC2. Therefore, in the modification shown in FIGS. 9 and 10, as shown in column B of FIG. 9 and column D of FIG. 10, it is determined at time t3 that the capacity difference ΔC is zero and therefore has not reached the second capacity difference ΔC2 (S250: NO in FIG. 5), and the constant current control (capacity-referenced constant current control P2) is further continued. Then, as shown in column B of FIG. 9 and column E of FIG. 10, at time t4, the capacity difference ΔC reaches the second capacity difference ΔC2 (=−ΔFCC) (S250: YES in FIG. 5) and constant current control is stopped.

The FCC of each storage battery 12 may be estimated based on the SOH of each storage battery 12 estimated by the SOH estimation unit 68, for example. That is, the FCC of each storage battery 12 is calculated by multiplying the initial FCC of each storage battery 12 by the SOH. Alternatively, the FCC of each storage battery 12 may be estimated based on the capacity value between predetermined SOCs as measured by the coulomb counting processing unit 62. The method of estimating the FCC of each storage battery 12 is not limited to these, and other known estimation methods may be employed.

Thus, in the modification of the first embodiment shown in FIGS. 9 and 10, the control unit 60 sets the sign inversed value of the difference ΔFCC between the FCC of the discharge-side storage battery 12a and the FCC of the charge-side storage battery 12b as the second capacity difference ΔC2 for determining the stop timing of the capacity-referenced constant current control P2. Therefore, according to this modification, even if the FCC of each storage battery 12a, 12b varies, it is possible to equalize the capacity of each storage battery 12a, 12b so that the remaining capacity of each storage battery 12a, 12b becomes zero almost simultaneously at the time of discharge of the battery assembly 10, thereby extremely effectively extending the continuous operating time of the battery assembly 10.

### B. Second Embodiment

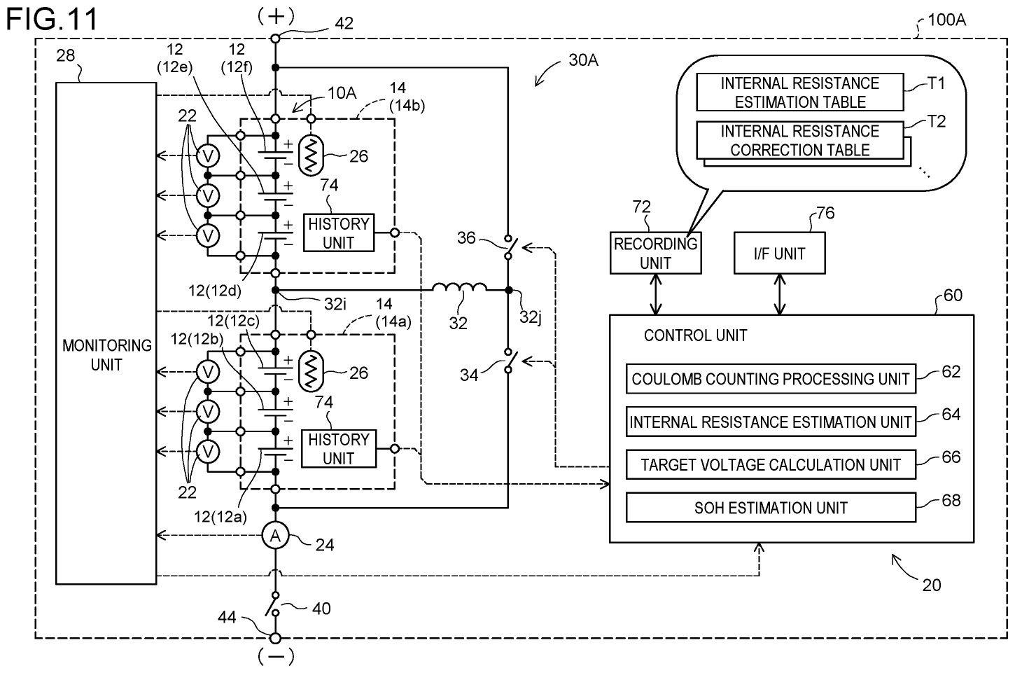

FIG. 11 is an explanatory view schematically illustrating a configuration of a battery device 100A in a second embodiment. In the following, the same configuration of the battery device 100A of the second embodiment as that of the battery device 100 of the first embodiment described above will be omitted in the description, as appropriate, by the use of the same symbols.

The battery device 100A of the second embodiment differs from the battery device 100 of the first embodiment in that the battery assembly 10A is composed of a plurality of battery modules 14 and is capable of performing voltage equalization on a per battery module 14 basis. Specifically, in the battery device 100A of the second embodiment, the battery assembly 10A includes six storage batteries (cells) 12 (12a, 12b, 12c, 12d, 12e, 120 connected in series with each other, three storage batteries 12 (12a, 12b, 12c) forming one battery module 14 (14a) and the remaining three storage batteries 12 (12d, 12e, 120 forming another battery module 14 (14b). In other words, the battery assembly 10A has a configuration in which the battery module 14a and the battery module 14b, which are composed of a plurality of storage batteries 12, are connected in series with each other. In the battery device 100A of the second embodiment, one thermometer 26 and one history unit 74 are provided for each battery module 14.

In the battery device 100A of the second embodiment, the voltage equalization circuit 30A is a circuit that executes constant current control to reduce the voltage difference of each of the plurality of battery modules 14 by transferring electric charge among the plurality of battery modules 14 constituting the battery assembly 10A. The voltage of each of the plurality of battery modules 14 may be the average of the voltages of the storage batteries 12 in each of the plurality of battery modules 14 or the sum of the voltages of the storage batteries 12 in each of the plurality of battery modules 14. The following describes a case in which the average value of the voltages of the storage batteries 12 contained in each of the plurality of battery modules 14 is used as the voltage of each of the plurality of battery modules 14. The voltage equalization circuit 30A has a coil 32, a first switch 34, and a second switch 36. One end 32i of the coil 32 is connected to the connection point between the positive terminal of the battery module 14a and the negative terminal of the battery module 14b. The first switch 34 is connected between the negative terminal of the battery module 14a and the other end 32j of the coil 32. The second switch 36 is connected between the positive terminal of the battery module 14b and the other end 32j of the coil 32.

In the battery device 100A of the second embodiment, the coulomb counting processing unit 62 calculates the capacity of each battery module 14 by integrating the current measured by the ammeter 24 and the monitoring unit 28 with the current during the constant current control in the voltage equalization process.

In the battery device 100A of the second embodiment, the target voltage calculation unit 66 sets the target voltage VMTa of the battery module 14a and the target voltage VMTb of the battery module 14b based on the module average voltage VMave, which is the average of the average voltage VMa of the battery module 14a and the average voltage VMb of the battery module 14b, and the internal resistance of each storage battery 12. More specifically, for the battery module 14a having a relatively high average voltage (hereinafter also referred to as “discharge-side battery module 14a”), a target voltage VMTa is set as the value obtained by subtracting an adjustment voltage VMth(a), which is set based on the internal resistance of each of the storage batteries 12 constituting the discharge-side battery module 14a, from the module average voltage VMave (VMTa=VMave−VMth(a)). For the battery module 14b having a relatively low average voltage (hereinafter also referred to as “charge-side battery module 14b”), a target voltage VMTb is set as the value obtained by adding an adjustment voltage VMth (b), which is set based on the internal resistance of each of the storage batteries 12 constituting the charge-side battery module 14b, to the module average voltage VMave (VMTb=VMave+VMth(b)). The relationship between the internal resistance of the storage battery 12 and each adjustment voltage is determined experimentally in advance, e.g., as the internal resistance of the storage battery 12 increases, the adjustment voltage is set to a higher value. The method of setting the target voltages VMTa and VMTb is not limited to this, and other known setting methods may be employed. The target voltage VMTa of the discharge-side battery module 14a is an example of the first target voltage, and the target voltage VMTb of the charge-side battery module 14b is an example of the second target voltage.

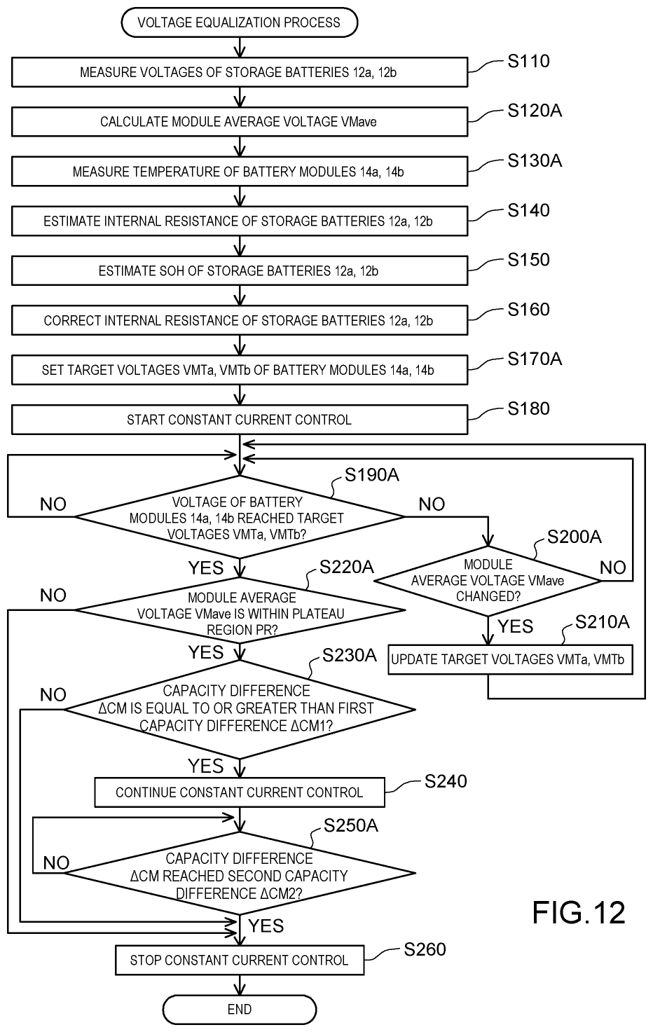

FIG. 12 is a flowchart illustrating a voltage equalization process performed in the battery device 100A of the second embodiment. The voltage equalization process performed in the battery device 100A of the second embodiment will be described below only in terms of the differences from the voltage equalization process of the first embodiment (FIG. 5).

The voltage equalization process of the second embodiment is a process that performs constant current control to reduce the difference between the average values of the voltages of the storage batteries 12 in each of the plurality of battery modules 14 constituting the battery assembly 10A by transferring electric charges among the battery modules 14. The voltage equalization process is started, e.g., automatically when the voltage difference among the plurality of battery modules 14 constituting the battery assembly 10A is detected to be larger than a predetermined threshold value, or in response to an instruction from the administrator.

The following describes the voltage equalization process to be performed for the pair of the battery module 14a (discharge-side battery module 14a) and the battery module 14b (charge-side battery module 14b) when the average voltage of each of the storage batteries 12 constituting the battery module 14a is relatively high and the average voltage of each of the storage batteries 12 constituting the battery module 14b is relatively low among the plurality of battery modules 14 constituting the battery assembly 10A. The discharge-side battery module 14a is an example of the first battery module and the charge-side battery module 14b is an example of the second battery module.

In S120A (FIG. 12), the module average voltage VMave, which is the average of the average voltage VMa of the discharge-side battery module 14a and the average voltage VMb of the charge-side battery module 14b, is calculated. In S130A, the temperatures of the battery modules 14a, 14b are measured, and in S170A, the target voltage VMTa of the discharge-side battery module 14a and the target voltage VMTb of the charge-side battery module 14b are set. The target voltage VMTa of the discharge-side battery module 14a is an example of the first target voltage, and the target voltage VMTb of the charge-side battery module 14b is an example of the second target voltage.

When constant current control is started in S180, it is monitored whether at least one of the average voltage VMa of the discharge-side battery module 14a and the average voltage VMb of the charge-side battery module 14b has reached the respective target voltages VMTa and VMTb (S190A), and whether the module average voltage VMave has changed (S200A), and if the module average voltage VMave has changed (S200A: YES), the target voltages VMTa and VMTb are updated based on the changed module average voltage VMave (S210A).

If at least one of the average voltage VMa of the discharge-side battery module 14a and the average voltage VMb of the charge-side battery module 14b reaches the respective target voltages VMTa and VMTb (S190A: YES), it is determined whether the module average voltage VMave is within the plateau region PR for at least one of the discharge-side battery module 14a and the charge-side battery module 14b (S220A), and the constant current control is stopped (S260) if it is determined that the module average voltage VMave is not within the plateau region PR (220A: NO).

On the other hand, if it is determined that the module average voltage VMave is within the plateau region PR (S220A: YES), the capacity difference ΔCM between the capacity CMa of the discharge-side battery module 14a and the capacity CMb of the charge-side battery module 14b calculated by the coulomb counting processing unit 62 (ΔCM=CMa−CMb) is identified, it is determined whether the capacity difference ΔCM is equal to or greater than the first capacity difference ΔCM1 (S230A), and if it is determined that the capacity difference ΔCM is smaller than the first capacity difference ΔCM1 (S230A: NO), the constant current control is stopped (S260).

On the other hand, if it is determined that the capacity difference ΔCM is equal to or greater than the first capacity difference ΔCM1 (S230A: YES), constant current control (capacity-referenced constant current control P2) is continued (S240), whether the capacity difference ΔCM has reached the predetermined second capacity difference ΔCM2 is monitored (S250A), and the constant current control is stopped (S260) when the capacity difference ΔCM reaches the second capacity difference ΔCM2. The absolute value of the second capacity difference ΔCM2 is smaller than the absolute value of the first capacity difference ΔCM1. The value of the second capacity difference ΔCM2 may be zero.

As described above, the storage battery management device 20 of the second embodiment is a device for managing the battery assembly 10A including the battery module 14a (discharge-side battery module 14a) and the battery module 14b (charge-side battery module 14b) connected in series, composed of at least one storage battery 12 having SOC-OCV characteristics including a plateau region PR. The storage battery management device 20 includes the voltmeter 22, the ammeter 24, the monitoring unit 28, the voltage equalization circuit 30A, the coulomb counting processing unit 62, the internal resistance estimation unit 64, the target voltage calculation unit 66, and the control unit 60. The voltmeter 22 and the monitoring unit 28 measure the voltage of each storage battery 12. The ammeter 24 and monitoring unit 28 measure the current flowing through the battery assembly 10. The voltage equalization circuit 30A performs constant current control to reduce the difference between the voltage of the discharge-side battery module 14a (average voltage VMa) and the voltage the charge-side battery module 14b (average voltage VMb) by transferring electric charge from the discharge-side battery module 14a to the charge-side battery module 14b. The coulomb counting processing unit 62 integrates the current measured by the ammeter 24 and the monitoring unit 28 with the current during the above constant current control to calculate the capacity of the battery modules 14a, 14b. The internal resistance estimation unit 64 estimates the internal resistance of each storage battery 12. The target voltage calculation unit 66 sets the target voltage VMTa of the discharge-side battery module 14a and the target voltage VMTb of the charge-side battery module 14b based on the module average voltage VMave, which is the average of the voltage of the discharge-side battery module 14a (average voltage VMa) and the voltage of the charge-side battery module 14b (average voltage VMb) measured by the voltmeter 22 and the monitoring unit 28, and the internal resistance estimated by the internal resistance estimation unit 64. The control unit 60 controls the voltage equalization circuit 30A to cause the voltage equalization circuit 30A to perform the above constant current control.

If the module average voltage VMave is within the plateau region PR for at least one of the discharge-side battery module 14a and the charge-side battery module 14b (S220A: YES in FIG. 12), when the voltage of the discharge-side battery module 14a (average voltage VMa) reaches the target voltage VMTa or the voltage of the charge-side battery module 14b (average voltage VMb) reaches the target voltage VMTb during the above constant current control (voltage-referenced constant current control P1), the control unit 60 identifies the capacity difference ΔCM between the capacity CMa of the discharge-side battery module 14a and the capacity CMb of the charge-side battery module 14b calculated by the coulomb counting processing unit 62 (ΔCM=CMa−CMb), and if the capacity difference ΔCM is equal to or greater than the predetermined first capacity difference ΔCM1 (S230A: YES), continues the constant current control (capacity-referenced constant current control P2)(S240), and stops the constant current control (S260) when the capacity difference ΔCM reaches the predetermined second capacity difference ΔCM2 (S250A: YES), the absolute value of the second capacity difference ΔCM2 being smaller than the absolute value of the first capacity difference ΔCM1.

Thus, according to the storage battery management device 20 of the second embodiment, in a battery assembly 10A in which a plurality of battery modules 14, each composed of at least one storage battery 12 having SOC-OCV characteristics including a plateau region PR, are connected in series, even when the module average voltage VMave of the two battery modules 14a, 14b is within the plateau region PR and the constant current control (voltage-referenced constant current control P1) referring to the target voltages VMTa, VMTb may not be sufficient to accurately equalize the remaining capacity of each battery module 14a, 14b, by performing constant current control (capacity-referenced constant current control P2) referring to the capacity difference Δ MC of the two battery modules 14a, 14b, it is possible to accurately equalize the remaining capacity of each battery module 14a, 14b, thereby effectively extending the continuous operating time of the battery assembly 10A.

### C. Third Embodiment

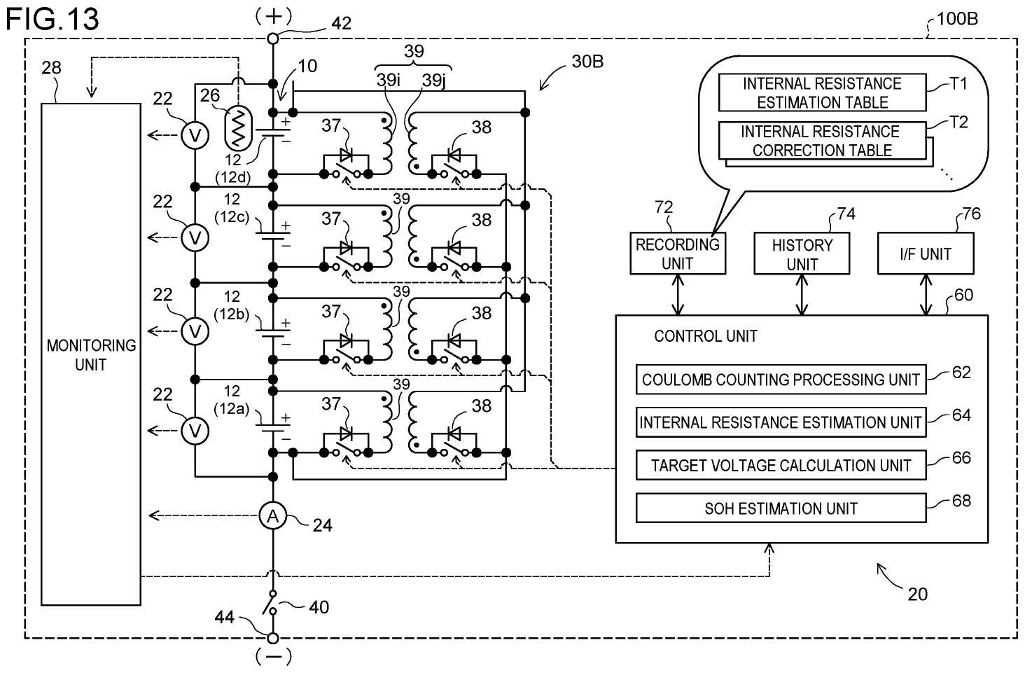

FIG. 13 is an explanatory view schematically illustrating a configuration of a battery device 100B of a third embodiment. In the following, the same configuration of the battery device 100B of the third embodiment as that of the battery device 100 of the first embodiment described above will be omitted in the description, as appropriate, by the use of the same symbols.

The battery device 100B of the third embodiment differs from the battery device 100 of the first embodiment in the configuration of the voltage equalization circuit 30B. Specifically, while the voltage equalization circuit 30 included in the battery device 100 of the first embodiment is configured to be able to perform voltage equalization for each pair of two mutually adjacent storage batteries 12, the voltage equalization circuit 30B included in the battery device 100B of the third embodiment is configured to be able to perform voltage equalization for any combination of the storage batteries 12, not limited to a pair of two storage batteries 12 adjacent to each other.

Specifically, the voltage equalization circuit 30B in the third embodiment has one transformer 39 for each storage battery 12. Each transformer 39 has a first winding 39i and a second winding 39j. The first winding 39i of each transformer 39 is connected in parallel to the corresponding storage battery 12. The second winding 39j of each transformer 39 is connected in parallel to the battery assembly 10. The voltage equalization circuit 30B also includes a first switch 37 and a second switch 38, one for each storage battery 12. Each first switch 37 is connected in series with the first winding 39i of the transformer 39 provided for each storage battery 12, and each second switch 38 is connected in series with the second winding 39j of the transformer 39 provided for each storage battery 12. Each first switch 37 and each second switch 38 are controlled on and off by the control unit 60.

The voltage equalization circuit 30B with this configuration can individually perform constant current control for each of the storage batteries 12, which reduces the voltage difference of each of the plurality of storage batteries 12 by transferring electric charge among the plurality of storage batteries 12. In other words, at least one storage battery 12 of the plurality of storage batteries 12 for which the difference between the respective voltages of the plurality of storage batteries 12 measured by the voltmeter 22 and the monitoring unit 28, and the average voltage Vave of the plurality of storage batteries 12 is greater than a predetermined value is identified as the target storage battery 12x, and constant current control can be performed for the target storage battery 12x to bring the voltage of the target storage battery 12x closer to the average voltage Vave.

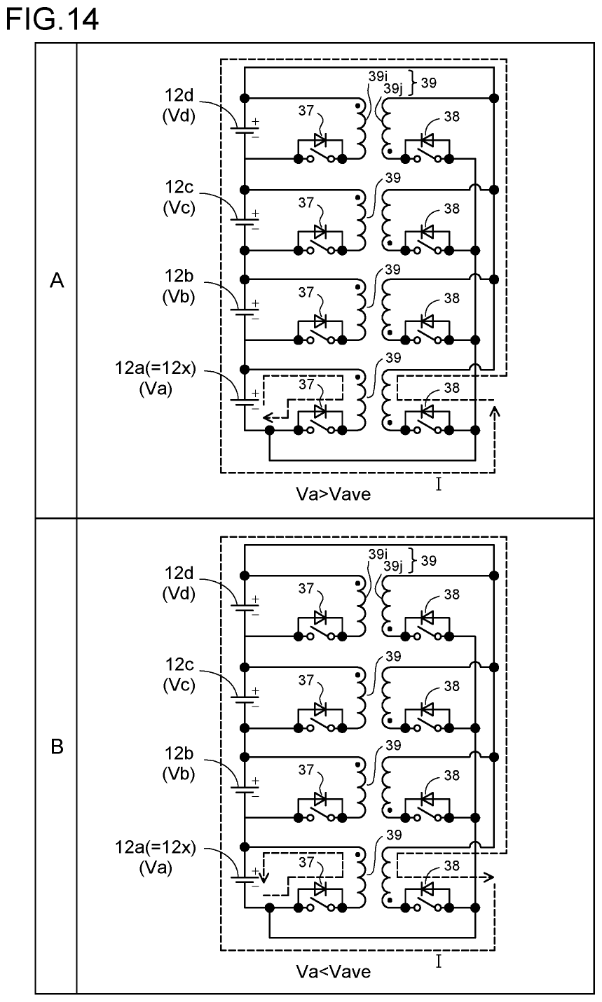

FIG. 14 is an explanatory view schematically illustrating an operation of the constant current control when one storage battery 12a among a plurality of storage batteries 12 is identified as the target storage battery 12x. Column A of FIG. 14 shows a state in which the voltage Va of the storage battery 12a, which is the target storage battery 12x, is higher than the average voltage Vave of each storage battery 12, and voltage equalization is performed by transferring electric charge from the target storage battery 12x to the other storage batteries 12. Column B of FIG. 14 shows a state in which the voltage Va of the storage battery 12a, which is the target storage battery 12x, is lower than the average voltage Vave of each storage battery 12, and voltage equalization is performed by transferring electric charge from the other storage batteries 12 to the target storage battery 12x.

In the battery device 100B of the third embodiment, the target voltage calculation unit 66 identifies at least one target storage battery 12x described above and sets the target voltage VTx for each target storage battery 12x based on the average voltage Vave of each storage battery 12 and the internal resistance estimated by the internal resistance estimation unit 64. More specifically, if the voltage Vx of the target storage battery 12x is higher than the average voltage Vave, the value obtained by subtracting an adjustment voltage Vth(x), which is set based on the internal resistance of the target storage battery 12x, from the average voltage Vave is set as the target voltage VTx (VTx=Vave−Vth(x)). In contrast, if the voltage Vx of the target storage battery 12x is lower than the average voltage Vave, the value obtained by adding the adjustment voltage Vth(x), which is set based on the internal resistance of the target storage battery 12x, to the average voltage Vave is set as the target voltage VTx (VTx=Vave+Vth(x)). The relationship between the internal resistance of the storage battery 12 and the adjustment voltage is determined experimentally in advance, e.g., as the internal resistance of the storage battery 12 increases, the adjustment voltage is set to a higher value. The method of setting the target voltage VTx is not limited to this, and other known setting methods may be employed.

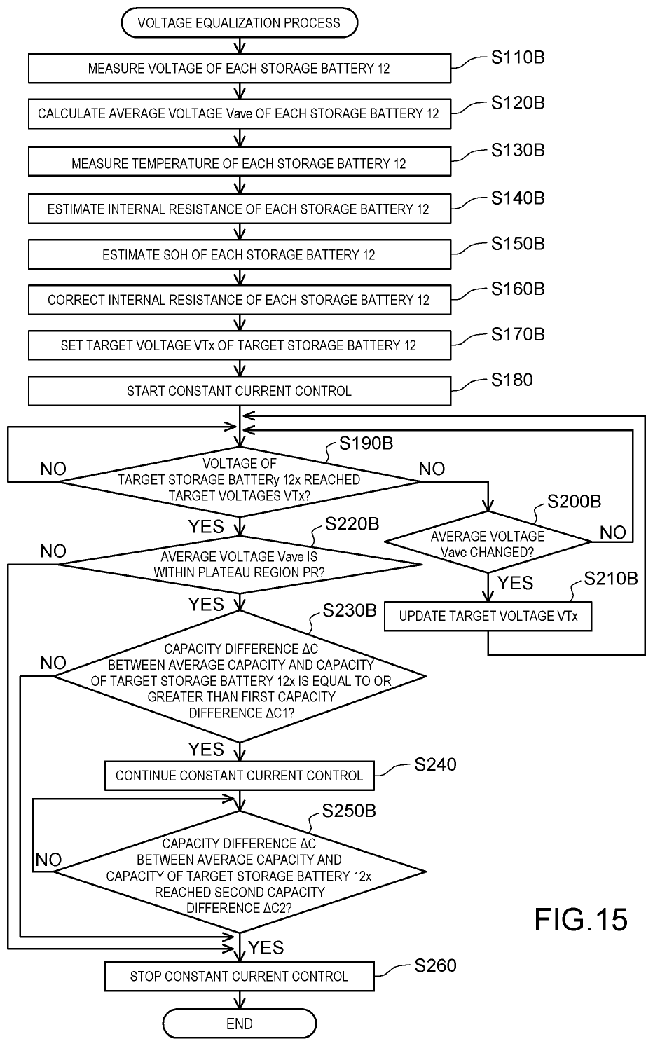

FIG. 15 is a flowchart illustrating a voltage equalization process performed in the battery device 100B of the third embodiment. The voltage equalization process performed in the battery device 100B of the third embodiment will be described below only in terms of the differences from the voltage equalization process of the first embodiment (FIG. 5).

The voltage equalization process of the third embodiment is a process that executes constant current control to reduce the difference in the voltage of each storage battery 12 by transferring electric charge between the target storage battery 12x and the other storage batteries 12 for the target storage battery 12x of the plurality of storage batteries 12 constituting the battery assembly 10 the voltage value of which is more than a predetermined value away from the average voltage Vave of the plurality of storage batteries 12. The voltage equalization process is started, e.g., automatically when the target storage battery 12x is detected among the multiple storage batteries 12 constituting the battery assembly 10, or in response to an instruction from the administrator.

In S110B (FIG. 15), the voltage of each storage battery 12 is measured. The measurement of the voltage of each storage battery 12 is continuously performed during the voltage equalization process. In S120B, the average voltage Vave, which is the average of the voltages of each storage battery 12, is calculated.

In S130B, the temperature of each storage battery 12 is measured, in S140B, the internal resistance of each storage battery 12 is estimated, in S150B, the SOH of each storage battery 12 is estimated, and in S160B, the internal resistance of each storage battery 12 is corrected. These processes may be performed only for the target storage battery 12x.

In S170B, the target voltage VTx of the target storage battery 12x is set. When constant current control is started in S180, it is monitored whether the voltage Vx of the target storage battery 12x has reached the target voltage VTx (S190B) and whether the average voltage Vave has changed (S200B), and if the average voltage Vave has changed (5200B: YES), the target voltage VTx is updated based on the changed average voltage Vave (S210B).

When the voltage Vx of the target storage battery 12x reaches the target voltage VTx (S190B: YES), it is determined whether the average voltage Vave is within the plateau region PR for at least one storage battery 12 (S220B), and if the average voltage Vave is not within the plateau region PR (S220B: NO), the constant current control is stopped (S260).

On the other hand, if it is determined that the average voltage Vave is within the plateau region PR (S220B: YES), the capacity difference ΔC between the average capacity Cave of each storage battery 12 calculated by the coulomb counting processing unit 62 and the capacity Cx of the target storage battery 12x is identified (if Cave≥Cx, then ΔC=Cave−Cx, and if Cave<Cx, then ΔC=Cx−Cave), and whether the capacity difference ΔC is equal to or greater than the predetermined first capacity difference ΔC1 is determined (S230B), and if the capacity difference ΔC is determined to be smaller than the predetermined first capacity difference ΔC1 (S230B: NO), the constant current control is stopped (S260).

On the other hand, if it is determined that the capacity difference ΔC is equal to or greater than the first capacity difference ΔC1 (S230B: YES), the constant current control (capacity-referenced constant current control P2) is continued (S240), and whether the capacity difference ΔC has reached the predetermined second capacity difference ΔC2 is monitored (S250B), and the constant current control is stopped when the capacity difference ΔC reaches the second capacity difference ΔC2 (S260). The absolute value of the second capacity difference ΔC2 is smaller than the absolute value of the first capacity difference ΔC1. The value of the second capacity difference ΔC2 may be zero.

As described above, the storage battery management device 20 of the third embodiment is a device for managing a battery assembly 10 in which a plurality of storage batteries 12 having SOC-OCV characteristics including a plateau region PR are connected in series. The storage battery management device 20 has the voltmeter 22, the ammeter 24, the monitoring unit 28, the voltage equalization circuit 30B, the coulomb counting processing unit 62, the internal resistance estimation unit 64, the target voltage calculation unit 66, and the control unit 60. The voltmeter 22 and the monitoring unit 28 measure the voltage of each storage battery 12. The ammeter 24 and monitoring unit 28 measure the current flowing through the battery assembly 10. The voltage equalization circuit 30B is a circuit capable of performing constant current control for each of the storage batteries 12 individually to reduce the voltage difference of each storage battery 12 by transferring electric charge among the plurality of storage batteries 12. The coulomb counting processing unit 62 calculates the capacity of each storage battery 12 by integrating the current measured by the ammeter 24 and the monitoring unit 28 with the current during the above constant current control. The internal resistance estimation unit 64 estimates the internal resistance of each storage battery 12. The target voltage calculation unit 66 identifies at least one storage battery 12 for which the difference between the voltage of each storage battery 12 measured by the voltmeter 22 and the monitoring unit 28, and the average voltage Vave of the voltage of each storage battery 12 is greater than a predetermined value as the target storage battery 12x and, sets the target voltage VTx of each target storage battery 12x based on the average voltage Vave and the internal resistance estimated by the internal resistance estimation unit. The control unit 60 controls the voltage equalization circuit 30B to cause the voltage equalization circuit 30B to perform the above constant current control.

If the average voltage Vave is within the plateau region PR of at least one storage battery 12 (S220B: YES in FIG. 15), when the voltage Vx of the target storage battery 12x reaches the target voltage VTx during the above constant current control (voltage-referenced constant current control P1), the control unit 60 identifies the capacity difference ΔC between the average capacity Cave of each storage battery 12 calculated by the coulomb counting processing unit 62 and the capacity Cx of the target storage battery 12x, and if the capacity difference ΔC is equal to or greater than the predetermined first capacity difference ΔC1 (S230B: YES), continues the constant current control (capacity-referenced constant current control P2) (S240), and stops the constant current control (S260) when the capacity difference ΔC reaches the predetermined second capacity difference ΔC2 (S250B: YES), the absolute value of the second capacity difference ΔC2 being smaller than the absolute value of the first capacity difference ΔC1).

Thus, according to the storage battery management device 20 of the third embodiment, in a battery assembly 10 in which a plurality of storage batteries 12 having SOC-OCV characteristics including a plateau region PR are connected in series, even when the average voltage Vave of each storage battery 12 is within the plateau region PR and the constant current control (voltage-referenced constant current control P1) referring to the target voltage VTx may not be sufficient to accurately equalize the remaining capacity of each storage battery 12, by performing constant current control (capacity-referenced constant current control P2) referring to the capacity difference ΔC of each storage battery 12, it is possible to accurately equalize the remaining capacity of each storage battery 12, thereby effectively extending the continuous operating time of the battery assembly 10.

### D. Modifications

The technology disclosed herein is not limited to the embodiments described above, but can be modified into various forms without departing from the spirit of the present invention, for example, the following modifications are possible.

The configuration of the battery device 100 in the above embodiments is merely an example and may be modified in various ways. For example, in each of the above embodiments, the number of storage batteries 12 constituting the battery assembly 10 may be modified as desired. In each of the above embodiments, one thermometer 26 may be provided for each of the storage batteries 12. The thermometer 26 may be omitted.

In each of the above embodiments, the contents of the internal resistance estimation table T1 and the internal resistance correction table T2 are merely examples and can be modified in various ways. It is not necessary that the internal resistance estimation table T1 and/or the internal resistance correction table T2 be recorded in the recording unit 72. In each of the above embodiments, at least one of each functional unit of the control unit 60 may be omitted.

The contents of the voltage equalization process in each of the above embodiments are merely examples and can be modified in various ways. For example, in the first embodiment above, the temperature of the storage battery 12 is measured (S130 in FIG. 5), but if the temperature measurement value of the storage battery 12 is unnecessary for the estimation of the internal resistance of the storage battery 12 (S140 in FIG. 5), the temperature measurement of the storage battery 12 may be omitted. Further, in the first embodiment above, the estimation of the SOH of the storage battery 12 (S150 in FIG. 5) is performed, but if the value of the SOH of the storage battery 12 is unnecessary for the correction of the internal resistance of the storage battery 12 (S160 in FIG. 5), the estimation of the SOH of the storage battery 12 may be omitted. The correction of the internal resistance of storage battery 12 (S160 in FIG. 5) may also be omitted. In the first embodiment above, monitoring of changes in the average voltage (S200) and updating of the target voltage (S210) are performed during constant current control, but these processes may be omitted.

In the modification of the first embodiment above, the second capacity difference ΔC2 for determining the stop timing of the capacity-referenced constant current control P2 is set to the same value as the sign inversed value of the difference ΔFCC(=−ΔFCC), between the FCC of the discharge-side storage battery 12a and the FCC of the charge-side storage battery 12b, but the second capacity difference ΔC2 may be set by other methods (e.g., by setting the second capacity difference ΔC2 to a value close to −ΔFCC) based on the difference ΔFCC.

In the above third embodiment, each storage battery 12 may be replaced by a battery module in which at least one storage battery 12 is connected in series.

### REFERENCE SIGNS LIST

10: battery assembly, 12: storage battery, 14: battery module, 20: storage battery management device, 22: voltmeter, 24: ammeter, 26: thermometer, 28: monitoring unit, 30: voltage equalization circuit, 32: coil, 32i: one end, 32j: other end, 34: first switch, 36: second switch, 37: first switch, 38: second switch, 39: transformer, 39i: first winding, 39j: second winding, 40: line switch, 42: positive terminal, 44: negative terminal, 60: control unit, 62: coulomb counting processing unit, 64: internal resistance estimation unit, 66: target voltage calculation unit, 68: SOH estimation unit, 72: recording unit, 74: history unit, 76: interface unit, 100: battery device, PR: plateau region, T1: internal resistance estimation table, T2: internal resistance correction table

1. A storage battery management device for managing a battery assembly in which a first storage battery and a second storage battery having SOC-OCV characteristics including a plateau region are connected in series, the storage battery management device comprising:
a voltage measuring unit that measures the voltage of each of the first storage battery and the second storage battery;
a current measuring unit that measures the current flowing through the battery assembly;
a voltage equalization circuit that performs constant current control to reduce the difference between the voltage of the first storage battery and the voltage of the second storage battery by transferring electric charge between the first storage battery and the second storage battery;
a coulomb counting processing unit that integrates the current measured by the current measuring unit with the current during the constant current control to calculate the respective capacities of the first storage battery and the second storage battery;
an internal resistance estimation unit that estimates the internal resistance of each of the first storage battery and the second storage battery;
a target voltage calculation unit that sets a first target voltage for the first storage battery and a second target voltage for the second storage battery based on an average voltage of the voltage of the first storage battery and the voltage of the second storage battery measured by the voltage measuring unit and the internal resistance estimated by the internal resistance estimation unit; and
a voltage equalization control unit that controls the voltage equalization circuit to cause the voltage equalization circuit to perform the constant current control, wherein
if the average voltage is within the plateau region for at least one of the first storage battery and the second storage battery, when the voltage of the first storage battery reaches the first target voltage or the voltage of the second storage battery reaches the second target voltage during the constant current control, the voltage equalization control unit identifies the capacity difference between the capacity of the first storage battery and the capacity of the second storage battery calculated by the coulomb counting processing unit, and continues the constant current control when the capacity difference is greater than or equal to a predetermined first capacity difference, and stops the constant current control when the capacity difference reaches a predetermined second capacity difference, the absolute value of the second capacity difference being smaller than the absolute value of the first capacity difference.

2. The storage battery management device according to claim 1, wherein
when the average voltage changes during the constant current control, the target voltage calculation unit updates the first target voltage and the second target voltage based on the average voltage after the change.

3. The storage battery management device according to claim 1, wherein
the voltage equalization control unit sets the second capacity difference based on the difference between the FCC of the first storage battery and the FCC of the second storage battery.

4. The storage battery management device according to claim 3, wherein
the voltage equalization control unit sets a sign inversed value of the difference between the FCC of the first storage battery and the FCC of the second storage battery as the second capacity difference.

5. The storage battery management device according to claim 1, further comprising:
an SOH estimation unit that estimates the SOH of each of the first storage battery and the second storage battery, wherein
the target voltage calculation unit corrects the internal resistance of each of the first storage battery and the second storage battery based on the SOH of each of the first storage battery and the second storage battery estimated by the SOH estimation unit, and sets the first target voltage and the second target voltage based on the corrected internal resistance.

6. The storage battery management device according to claim 1, further comprising:
a history unit that records the history of the current integrated amount of charge or discharge obtained by the coulomb counting processing unit and the integrated time of the charge or discharge, wherein
the target voltage calculation unit calculates the number of charge/discharge cycles based on the history recorded in the history unit, corrects the internal resistance of the first storage battery and the second storage battery based on the number of charge/discharge cycles, and sets the first target voltage and the second target voltage based on the corrected internal resistance.

7. The storage battery management device according to claim 6, further comprising:
a communication unit for communicating with the outward, wherein
the history recorded in the history unit is updatable via the communication unit.

8. The storage battery management device according to claim 1, further comprising:
a battery temperature measuring unit that measures the temperature of at least one of the first storage battery and the second storage battery; and
a recording unit having previously recorded table data in which battery voltage, battery temperature, and battery internal resistance are associated with each other, wherein
the internal resistance estimation unit refers to the table data to estimate the internal resistance based on the average voltage and the battery temperature.

9. The storage battery management device according claim 1, wherein
if the average voltage is within the plateau region for at least one of the first storage battery and the second storage battery, when the voltage of the first storage battery reaches the first target voltage or the voltage of the second storage battery reaches the second target voltage during the constant current control, the voltage equalization control unit identifies the capacity difference between the capacity of the first storage battery and the capacity of the second storage battery calculated by the coulomb counting processing unit, and stops the constant current control when the capacity difference is smaller than the first capacity difference.

10. The storage battery management device according to claim 1, wherein
if the average voltage is not within the plateau region of either the first storage battery and the second storage battery, when the voltage of the first storage battery reaches the first target voltage or the voltage of the second storage battery reaches the second target voltage during the constant current control, the voltage equalization control unit stops the constant current control.

11. The storage battery management device according to claim 1, wherein
the first storage battery is a first battery module including a plurality of cells, and the second storage battery is a second battery module including a plurality of cells.

12. A storage battery management device for managing a battery assembly in which a plurality of storage batteries having SOC-OCV characteristics including a plateau region are connected in series, the storage battery management device comprising:
a voltage measuring unit that measures the voltage of each of the plurality of storage batteries;
a current measuring unit that measures the current flowing through the battery assembly;
a voltage equalization circuit that performs constant current control for each of the plurality of storage batteries individually to reduce the voltage difference of each of the plurality of storage batteries by transferring electric charge among the plurality of storage batteries;
a coulomb counting processing unit that integrates the current measured by the current measuring unit with the current during the constant current control to calculate the capacity of each of the plurality of storage batteries;
an internal resistance estimation unit that estimates the internal resistance of each of the plurality of storage batteries;
a target voltage calculation unit that identifies at least one storage battery of the plurality of storage batteries in which the difference between the voltage of each of the plurality of storage batteries measured by the voltage measuring unit and the average voltage of the plurality of storage batteries is more than a predetermined value as a target storage battery, and sets a target voltage for each of the target storage batteries based on the average voltage and the internal resistance estimated by the internal resistance estimation unit; and
a voltage equalization control unit that controls the voltage equalization circuit to cause the voltage equalization circuit to perform the constant current control for each of the target storage batteries individually, wherein
if the average voltage is within the plateau region, the voltage equalization control unit identifies, for the target storage battery that has reached the target voltage during the constant current control, a capacity difference from the average capacity of each of the plurality of storage batteries calculated by the coulomb counting processing unit, and continues the constant current control for the target storage battery for which the capacity difference is equal to or greater than a predetermined first capacity difference, and stops the constant current control for the target storage battery for which the capacity difference has reached a predetermined second capacity difference, the absolute value of the second capacity difference being smaller than the absolute value of the first capacity difference.

13. The storage battery management device according to claim 12, wherein
when the average voltage changes during the constant current control, the target voltage calculation unit updates the target voltage of each target storage battery based on the average voltage after the change.

14. The storage battery management device according to claim 12, wherein
the voltage equalization control unit sets the second capacity difference based on the difference between the FCC of the target storage battery and an average FCC of the plurality of storage batteries.

15. The storage battery management device according to claim 14, wherein
the voltage equalization control unit sets a sign inversed value of the difference between the FCC of the target storage battery and the average FCC as the second capacity difference.

16. The storage battery management device according to claim 12, further comprising
an SOH estimation unit that estimates the SOH of each of the plurality of storage batteries, wherein
the target voltage calculation unit corrects the internal resistance of the target storage batteries based on the SOH of the target storage batteries estimated by the SOH estimation unit, and sets the target voltage based on the corrected internal resistance.

17. The storage battery management device according to claim 12, further comprising:
a history unit that records the history of the current integrated amount of charge or discharge obtained by the coulomb counting processing unit and the integrated time of the charge or discharge, wherein
the target voltage calculation unit calculates the number of charge/discharge cycles based on the history recorded in the history unit, corrects the internal resistance of the target storage battery based on the number of charge/discharge cycles, and sets the target voltage based on the corrected internal resistance.

18. The storage battery management device according to claim 17, further comprising:
a communication unit for communicating with the outward, wherein
the history recorded in the history unit is updatable via the communication unit.

19. The storage battery management device according to claim 12, further comprising:
a battery temperature measuring unit that measures the temperature of at least one of the plurality of storage batteries; and
a recording unit having previously recorded table data in which battery voltage, battery temperature, and battery internal resistance are associated with each other, wherein
the internal resistance estimation unit refers to the table data and estimates the internal resistance based on the average voltage and the battery temperature.

20-22. (canceled)

23. A method for managing a battery device that comprises:
a battery assembly comprising a first storage battery and a second storage battery having SOC-OCV characteristics including a plateau region and connected in series;
a voltage measuring unit that measures the voltage of each of the first storage battery and the second storage battery;
a current measuring unit that measures the current flowing through the battery assembly; and
a voltage equalization circuit that performs constant current control to reduce the difference between the voltage of the first storage battery and the voltage of the second storage battery by transferring electric charge between the first storage battery and the second storage battery,
the method comprising:
a step of integrating the current measured by the current measuring unit with the current during the constant current control to calculate the respective capacities of the first storage battery and the second storage battery;
a step of estimating the internal resistance of each of the first storage battery and the second storage battery;
a step of setting a first target voltage of the first storage battery and a second target voltage of the second storage battery based on an average voltage of the voltage of the first storage battery and the voltage of the second storage battery measured by the voltage measuring unit and the internal resistance estimated in the step of estimating the internal resistance; and
a step of controlling the voltage equalization circuit to cause the voltage equalization circuit to perform the constant current control, wherein
the step of controlling the voltage equalization circuit to cause the voltage equalization circuit to perform the constant current control is a step of, if the average voltage is within the plateau region for at least one of the first storage battery and the second storage battery, when the voltage of the first storage battery reaches the first target voltage or the voltage of the second storage battery reaches the second target voltage during the constant current control, identifying the capacity difference between the capacity of the first storage battery and the capacity of the second storage battery calculated in the step of calculating the capacity, and continuing the constant current control when the capacity difference is greater than or equal to a predetermined first capacity difference, and stopping the constant current control when the capacity difference reaches a predetermined second capacity difference, the absolute value of the second capacity difference being smaller than the absolute value of the first capacity difference.

24. (canceled)
